(19) United States
(12) Patent Application Publication
(10) Pub. No.: US 2024/0147708 A1
(43) Pub. Date: May 2, 2024

(54) SEMICONDUCTOR DEVICE

(71) Applicant: Semiconductor Energy Laboratory Co., Ltd., Atsugi-shi, Kanagawa-ken (JP)

(72) Inventors: Takanori MATSUZAKI, Atsugi (JP); Yuki OKAMOTO, Ebina (JP); Tatsuya ONUKI, Atsugi (JP); Hitoshi KUNITAKE, Machida (JP)

(21) Appl. No.: 18/288,413

(22) PCT Filed: Apr. 26, 2022
(86) PCT No.: PCT/IB22/53840

§ 371 Date: Oct. 26, 2023

(30) Foreign Application Priority Data
May 10, 2021 (JP) 2021-079594
May 10, 2021 (JP) 2021-079595

(51) Int. Cl. H10B 12/00; H01L 25/065; H10B 10/00; H10B 41/27; H10B 41/40; H10B 43/27; H10B 43/40; H10B 80/00

(52) U.S. Cl. CPC H10B 12/50; H01L 25/0657; H10B 10/125; H10B 10/18; H10B 12/33; H10B 41/27; H10B 41/40; H10B 43/27; H10B 43/40; H10B 80/00

(57) ABSTRACT

A semiconductor device having a novel structure is provided. The semiconductor device includes a first substrate provided with a first peripheral circuit having a function of driving a first memory cell and a first memory cell layer including a second substrate and a first element layer including the first memory cell. The first memory cell includes a first transistor and a first capacitor. The first transistor includes a semiconductor layer including a metal oxide in its channel formation region. The first memory cell layer is provided to be stacked over the first substrate in a direction perpendicular or substantially perpendicular to a surface of the first substrate. The second substrate includes a circuit for performing writing of data to or reading of data from the first memory cell. The first peripheral circuit and the first memory cell are electrically connected to each other through a first through electrode provided in the second substrate and the first element layer.

### TECHNICAL FIELD

In this specification, a semiconductor device and the like will be described.

In this specification, a semiconductor device refers to a device that utilizes semiconductor characteristics, and means a circuit including a semiconductor element (a transistor, a diode, a photodiode, or the like), a device including the circuit, and the like. The semiconductor device also means all devices that can function by utilizing semiconductor characteristics. For example, an integrated circuit, a chip including an integrated circuit, and an electronic component including a chip in a package are examples of the semiconductor device. Moreover, a memory device, a display device, a light-emitting apparatus, a lighting device, an electronic device, and the like themselves may be semiconductor devices or may each include a semiconductor device.

### BACKGROUND ART

As a semiconductor applicable to a transistor, a metal oxide has been attracting attention. It has been reported that a transistor including a metal oxide semiconductor in a channel formation region (hereinafter referred to as an “oxide semiconductor transistor” or an “OS transistor” in some cases) has an extremely low off-state current (e.g., Non-Patent Documents 1 and 2). A variety of semiconductor devices using OS transistors have been manufactured (e.g., Non-Patent Documents 3 and 4).

The manufacturing process of an OS transistor can be incorporated in a CMOS process with a conventional Si transistor. For example, Patent Document 1 discloses a structure in which a plurality of memory cell array layers including OS transistors are stacked over a substrate provided with Si transistors.

### REFERENCES

### Patent Document

[Patent Document 1] United States Patent Application Publication No. 2012/0063208

### Non-Patent Documents

[Non-Patent Document 1] S. Yamazaki et al., “Properties of crystalline In—Ga—Zn-oxide semiconductor and its transistor characteristics,” Jpn. J. Appl. Phys., vol. 53, 04ED18 (2014).
[Non-Patent Document 2] K. Kato et al., “Evaluation of Off-State Current Characteristics of Transistor Using Oxide Semiconductor Material, Indium-Gallium-Zinc Oxide,” Jpn. J. Appl. Phys., vol. 51, 021201 (2012).
[Non-Patent Document 3] S. Amano et al., “Low Power LC Display Using In—Ga—Zn-Oxide TFTs Based on Variable Frame Frequency,” SID Symp. Dig. Papers, vol. 41, pp. 626-629 (2010).
[Non-Patent Document 4] T. Ishizu et al., “Embedded Oxide Semiconductor Memories: A Key Enabler for Low-Power VLSI,” ECS Tran., vol. 79, pp. 149-156 (2017).

### SUMMARY OF THE INVENTION

### Problems to be Solved by the Invention

An object of one embodiment of the present invention is to provide a semiconductor device or the like having a novel structure. Another object of one embodiment of the present invention is to provide a semiconductor device or the like functioning as a memory device that utilizes an extremely low off-state current and having a novel structure that allows a reduction of manufacturing cost. Another object of one embodiment of the present invention is to provide a semiconductor device or the like functioning as a memory device that utilizes an extremely low off-state current and having a novel structure that excels in low power consumption. Another object of one embodiment of the present invention is to provide a semiconductor device or the like functioning as a memory device that utilizes an extremely low off-state current and having a novel structure that allows a reduction in the size of the device. Another object of one embodiment of the present invention is to provide a semiconductor device or the like functioning as a memory device that utilizes an extremely low off-state current and having a novel structure that allows high reliability with small variations in electrical characteristics of transistors.

The description of a plurality of objects does not preclude the existence of each object. One embodiment of the present invention does not necessarily achieve all the objects described as examples. Furthermore, objects other than those listed are apparent from description of this specification, and such objects can be objects of one embodiment of the present invention.

### Means for Solving the Problems

One embodiment of the present invention is a semiconductor device including a first substrate provided with a first peripheral circuit having a function of driving a first memory cell and a first memory cell layer including a second substrate and a first element layer including the first memory cell, in which the first memory cell includes a first transistor and a first capacitor, in which the first transistor includes a semiconductor layer including a metal oxide in its channel formation region, in which the first memory cell layer is provided to be stacked over the first substrate in a direction perpendicular or substantially perpendicular to a surface of the first substrate, and in which the first peripheral circuit and the first memory cell are electrically connected to each other through a first through electrode provided in the second substrate and the first element layer.

One embodiment of the present invention is a semiconductor device including a first substrate provided with a first peripheral circuit having a function of driving a first memory cell and a first memory cell layer including a second substrate and a first element layer including the first memory cell, in which the first memory cell includes a first transistor and a first capacitor, in which the first transistor includes a semiconductor layer including a metal oxide in its channel formation region, in which the first memory cell layer is provided to be stacked over the first substrate in a direction perpendicular or substantially perpendicular to a surface of the first substrate, in which the second substrate includes an amplifier circuit for performing writing of data to or reading of data from the first memory cell, and in which the first peripheral circuit and the first memory cell are electrically connected to each other through a first through electrode provided in the second substrate and the first element layer.

In the semiconductor device of one embodiment of the present invention, the first memory cell layer preferably includes a plurality of the first element layers provided to be stacked in a direction perpendicular or substantially perpendicular to the surface of the first substrate.

In one embodiment of the present invention, the semiconductor device preferably includes the first substrate provided with a second peripheral circuit having a function of driving a second memory cell and a third substrate provided with a second memory cell layer including a second element layer including the second memory cell. It is preferable that the first memory cell layer be provided between the first substrate and the second memory cell layer, that the second memory cell include a second transistor and a second capacitor, that the second transistor include a semiconductor layer including silicon in its channel formation region, and that the second peripheral circuit and the second memory cell be electrically connected to each other through a second through electrode provided in the second substrate, the third substrate, the first element layer, and the second element layer.

In the semiconductor device of one embodiment of the present invention, the first substrate preferably includes a CPU and the second memory cell preferably has a function of retaining data retained by the CPU.

In one embodiment of the present invention, the semiconductor device preferably includes the first substrate provided with a second peripheral circuit having a function of driving a second memory cell and a second memory cell layer including a third substrate and a second element layer including the second memory cell. It is preferable that the first memory cell layer be provided between the first substrate and the second memory cell layer, that the second memory cell include a third transistor to a fifth transistor and a third capacitor, that the third transistor to the fifth transistor include semiconductor layers including a metal oxide in their channel formation regions, and that the second peripheral circuit and the second memory cell be electrically connected to each other through a second through electrode provided in the second substrate, the third substrate, the first element layer, and the second element layer.

In the semiconductor device of one embodiment of the present invention, the metal oxide contains In, Ga, and Zn. Preferably the semiconductor device.

Note that other embodiments of the present invention will be shown in the description of the following embodiments and the drawings.

### Effect of the Invention

With one embodiment of the present invention, a semiconductor device or the like having a novel structure can be provided. With one embodiment of the present invention, a semiconductor device or the like functioning as a memory device that utilizes an extremely low off-state current and having a novel structure that allows a reduction of manufacturing cost can be provided. With one embodiment of the present invention, a semiconductor device or the like functioning as a memory device that utilizes an extremely low off-state current and having a novel structure that excels in low power consumption can be provided. With one embodiment of the present invention, a semiconductor device or the like functioning as a memory device that utilizes an extremely low off-state current and having a novel structure that allows a reduction in the size of the device can be provided. With one embodiment of the present invention, a semiconductor device or the like functioning as a memory device that utilizes an extremely low off-state current and having a novel structure that allows high reliability with small variations in electrical characteristics of transistors can be provided.

The description of a plurality of effects does not preclude the existence of other effects. In addition, one embodiment of the present invention does not necessarily achieve all the effects described as examples. In one embodiment of the present invention, other objects, effects, and novel features are apparent from the description of this specification and the drawings.

### BRIEF DESCRIPTION OF THE DRAWINGS

FIG. 1 FIG. 1A to FIG. 1C are diagrams illustrating a structure example of a semiconductor device.

FIG. 2A and FIG. 2B are diagrams illustrating a structure example of a semiconductor device.

FIG. 3A to FIG. 3C are diagrams illustrating a structure example of a semiconductor device.

FIG. 4A and FIG. 4B are diagrams illustrating a structure example of a semiconductor device.

FIG. 5A to FIG. 5D are diagrams illustrating a structure example of a semiconductor device.

FIG. 6A and FIG. 6B are diagrams illustrating a structure example of a semiconductor device.

FIG. 7A to FIG. 7C are diagrams illustrating a structure example of a semiconductor device.

FIG. 8A and FIG. 8B are diagrams illustrating structure examples of a semiconductor device.

FIG. 9A and FIG. 9B are diagrams each illustrating a structure example of a semiconductor device.

FIG. 10A to FIG. 10C are diagrams illustrating a structure example of a semiconductor device.

FIG. 11 is a diagram illustrating a structure example of a semiconductor device.

FIG. 12 is a diagram illustrating a structure example of a semiconductor device.

FIG. 13A and FIG. 13B are diagrams illustrating a structure example of a semiconductor device.

FIG. 14 is a diagram illustrating a structure example of a semiconductor device.

FIG. 15 is a diagram illustrating a structure example of a semiconductor device.

FIG. 16A and FIG. 16B are diagrams illustrating a structure example of a semiconductor device.

FIG. 17A and FIG. 17B are diagrams illustrating structure examples of a semiconductor device.

FIG. 18 is a schematic cross-sectional view illustrating a structure example of a semiconductor device.

FIG. 19 is a schematic cross-sectional view illustrating a structure example of a semiconductor device.

FIG. 20 is a block diagram illustrating a structure example of a semiconductor device.

FIG. 21 is a conceptual diagram illustrating a structure example of a semiconductor device.

FIG. 22A and FIG. 22B are schematic diagrams illustrating examples of electronic components.

FIG. 23 is a diagram illustrating examples of electronic devices.

### MODE FOR CARRYING OUT THE INVENTION

Embodiments of the present invention will be described below. Note that one embodiment of the present invention is not limited to the following description, and it will be readily understood by those skilled in the art that modes and details of the present invention can be modified in various ways without departing from the spirit and scope of the present invention. One embodiment of the present invention therefore should not be construed as being limited to the following description of the embodiments.

Note that ordinal numbers such as “first”, “second”, and “third” in this specification and the like are used in order to avoid confusion among components. Thus, the ordinal numbers do not limit the number of components. In addition, the ordinal numbers do not limit the order of components. Furthermore, in this specification and the like, for example, a “first” component in one embodiment can be referred to as a “second” component in other embodiments or SCOPE OF CLAIMS. Moreover, in this specification and the like, for example, a “first” component in one embodiment can be omitted in other embodiments or SCOPE OF CLAIMS.

The same components, components having similar functions, components made of the same material, components formed at the same time, and the like in the drawings are denoted by the same reference numerals, and repeated description thereof is omitted in some cases.

In this specification, for example, a power supply potential VDD may be abbreviated to a potential VDD, VDD, or the like. The same applies to other components (e.g., a signal, a voltage, a circuit, an element, an electrode, and a wiring).

In the case where a plurality of components are denoted by the same reference numerals, and, particularly when they need to be distinguished from each other, an identification sign such as “_1”, “_2”, “[n]”, or “[m,n]” is sometimes added to the reference numerals. For example, a second wiring GL is referred to as a wiring GL[2].

### Embodiment 1

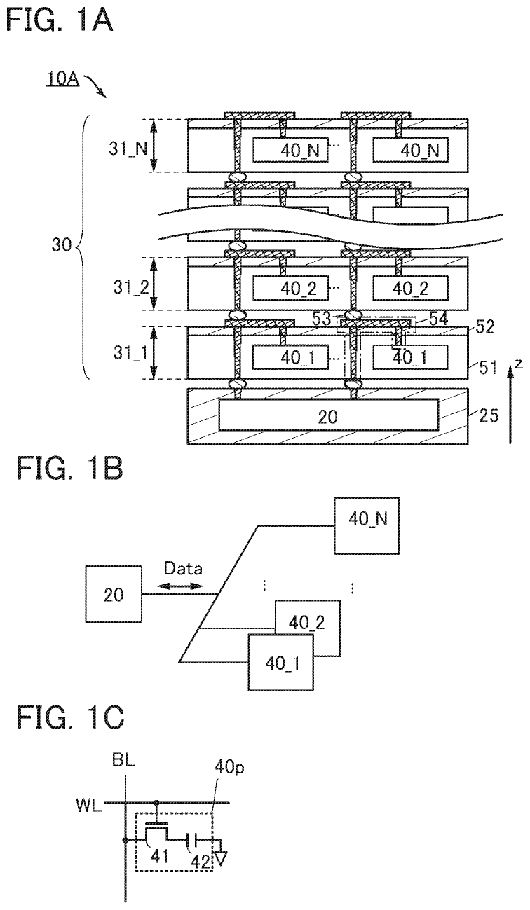

A structure example of a semiconductor device that is one embodiment of the present invention is described with reference to FIG. 1A to FIG. 1C. Note that a semiconductor device refers to a device that utilizes semiconductor characteristics, and means a circuit including a semiconductor element (a transistor, a diode, a photodiode, or the like) and a device including the circuit. The semiconductor device described in this embodiment has a function of a memory device that utilizes a transistor with an extremely low off-state current.

FIG. 1A is a schematic cross-sectional diagram of the semiconductor device described in this embodiment.

A semiconductor device 10A illustrated in FIG. 1A includes a peripheral circuit 20 provided in a substrate 25 and memory cell layers 31_1 to 31_N provided with a plurality of memory cells 40_1 to 40_N (N is an integer) which constitute a memory cell array. The memory cell layers 31_1 to 31_N are collectively referred to as a memory cell layer 30 in some cases. Note that although the description is made assuming that the substrate 25 in which the peripheral circuit 20 is provided is a silicon substrate, this embodiment is not limited thereto. Note that the silicon substrate refers to a substrate including silicon as a semiconductor material, for example, a single crystal silicon substrate. Note that, without being limited to silicon, a material containing Ge (germanium), SiGe (silicon germanium), GaAs (gallium arsenide), GaAlAs (gallium aluminum arsenide), or the like may be used for the substrate.

The peripheral circuit 20 includes circuits for outputting signals for driving the memory cells 40_1 to 40_N, such as a row driver and a column driver. The peripheral circuit 20 may be referred to as a control circuit, a driver circuit, or a circuit.

The row driver is a circuit having a function of outputting signals for driving the memory cells to word lines. The word line has a function of transmitting a word signal to the memory cells. The row driver is sometimes referred to as a word line driver circuit. Note that the row driver includes a decoder circuit for selecting a word line in accordance with a designated address, a buffer circuit, and the like. The column driver is a circuit having a function of outputting signals for driving the memory cells to bit lines, a function of outputting data to be written to the memory cells, and a function of amplifying data read from the memory cells to the bit lines. A bit line BL has a function of transmitting data to the memory cells. The column driver is sometimes referred to as a bit line driver circuit. Note that the column driver includes a sense amplifier, a precharge circuit, a decoder circuit for selecting a bit line in accordance with a designated address, and the like.

The peripheral circuit 20 preferably drives the memory cells 40_1 to 40_N at high speed. Thus, the peripheral circuit 20 preferably includes a transistor that operates at high speed. The transistor included in the peripheral circuit 20 is preferably a transistor that includes silicon in a channel formation region (a Si transistor) with high field-effect mobility.

Each of the memory cell layers 31_1 to 31_N includes an element layer 51 and a substrate 52. The element layer 51 is a layer including elements such as a transistor and a capacitor. The memory cells 40_1 to 40_N are provided in the element layers 51 in the memory cell layers 31_1 to 31_N, respectively. Although the number of the memory cells 40_1 to 40_N illustrated in each element layer 51 is two, three or more memory cells may be actually provided.

The memory cell layers 31_1 to 31_N are provided to be stacked in a direction perpendicular or substantially perpendicular to a surface of the substrate 25. In other words, the element layer 51 and the substrate 52 are provided to be stacked in a direction perpendicular or substantially perpendicular to the surface of the substrate 25. With this structure, the number of memory cells 40_1 to 40_N provided per unit area can be increased. Accordingly, the memory density can be increased. In the schematic cross-sectional diagram illustrated in FIG. 1A, the direction perpendicular or substantially perpendicular to the surface of the substrate 25 is defined as a z-axis direction in order to explain the position of components. Note that for easy understanding, the z-axis direction is sometimes referred to as a direction perpendicular to the surface of the substrate 25 in this specification. Note that “substantially perpendicular” refers to a state where an arrangement angle is greater than or equal to 85 degrees and less than or equal to degrees.

Through electrodes 54 provided in the memory cell layers 31_1 to 31_N and metal bumps provided between the through electrodes 54 function as a wiring for electrically connecting the peripheral circuit 20 and the memory cells 40_1 to 40_N. Since the through electrodes 54 and the metal bumps 53 functioning as the wiring can be provided in the direction perpendicular or substantially perpendicular to the surface of the substrate 25, the distance between the peripheral circuit 20 and the memory cells 40_1 to 40_N can be shortened. The through electrodes 54 and the metal bumps 53 can function as a bit line for writing or reading data to/from the memory cells 40_1 to 40_N or a word line for bringing the memory cells 40_1 to 40_N into a selected state.

FIG. 1B schematically illustrates a data signal Data between the peripheral circuit 20 and the memory cells 40_1 to 40_N. In the semiconductor device 10A in FIG. 1A, input/output of the data signal Data can be performed between the peripheral circuit 20 and the memory cells 40_1 to 40_N through the through electrodes 54 provided in the element layers 51 and the substrates 52 and the metal bumps 53 provided between the through electrodes 54. As described above, the distance between the peripheral circuit 20 and the memory cells 40_1 to 40_N can be shortened owing to the through electrodes 54 and the metal bumps 53 functioning as the wiring. Therefore, the peripheral circuit 20 can input and output the data signal Data to/from the memory cell layer N positioned in the upper layer as well as the memory cell layer 31_1 positioned in the lower layer.

The through electrodes 54 provided to penetrate the substrates 52 and the element layers 51 of the memory cell layers 31_1 to 31_N can be formed by a through electrode technique such as a TSV (Through Silicon Via) technique. The through electrodes 54 provided to penetrate each of the memory cell layers 31_1 to 31_N can be connected to each other via the metal bumps 53 (also referred to as micro-bumps) provided between the memory cell layers 31_1 to 31_N. The through electrodes 54 in each of the memory cell layers 31_1 to 31_N may be connected by Cu—Cu bonding without using the metal bumps 53. Note that the Cu—Cu bonding is a technique that establishes electrical continuity by connecting Cu (copper) pads. Alternatively, the through electrodes 54 may be directly connected to each other without using Cu (copper) pads.

A circuit structure of a memory cell that is applicable to the memory cells 40_1 to 40_N is illustrated in FIG. 1C. A memory circuit 40p illustrated in FIG. 1C includes a transistor 41 and a capacitor 42. One of a source and a drain of the transistor 41 is connected to a wiring BL. A gate of the transistor 41 is connected to a wiring WL. The other of the source and the drain of the transistor 41 is connected to the capacitor 42.

The transistor 41 is preferably an OS transistor. The off-state current of an OS transistor is extremely low. Accordingly, electric charge corresponding to data written to the memory cells 40_1 to 40_N can be retained in the capacitor 42 for a long time. In other words, data once written to the memory cells 40_1 to 40_N can be retained for a long time. Therefore, the frequency of data refresh can be reduced, and the power consumption of the semiconductor device of one embodiment of the present invention can be reduced.

The memory circuit 40p including the transistor 41 can be referred to as a DOSRAM (Dynamic Oxide Semiconductor Random Access Memory) using an OS transistor in a memory. The memory circuit can be formed using one transistor and one capacitor, so that a high-density memory can be achieved. In addition, with the use of an OS transistor, a data retention period can be extended.

Although a transistor having a top-gate structure or a bottom-gate structure without a back gate electrode is illustrated as the transistor 41, the structure of the transistor 41 is not limited thereto. The transistor 41 preferably includes a back gate electrode. Controlling a potential applied to the back gate electrode can control the threshold voltage of the transistor 41. Thus, the on-state current of the transistor 41 can be increased and the off-state current of the transistor can be decreased, for example.

In addition, the memory cells 40_1 to 40_N where OS transistors are used can be freely provided over an element layer including an OS transistor or the like; thus, integration is facilitated. Accordingly, the number of memory cells arranged per unit area can be increased, and the memory density can be increased.

Furthermore, an OS transistor has better electrical characteristics superior to those of a Si transistor in a high-temperature environment. Specifically, the ratio between an on-state current and an off-state current is large even at a high temperature higher than or equal to 125° C. and lower than or equal to 150° C.; thus, a favorable switching operation can be performed. The OS transistor operates favorably within the range from −40° C. to 190° C. In other words, the OS transistor has significantly high heat resistance. This heat resistance is higher than the heat resistance of a phase change memory (PCM) (higher than or equal to −40° C. and lower than or equal to 150° C.), the heat resistance of a resistance random access memory (ReRAM) (higher than or equal to −40° C. and lower than or equal to 125° C.), the heat resistance of a magnetoresistive random access memory (MRAM) (higher than or equal to −40° C. and lower than or equal to 105° C.), and the like.

Although the structure in which the memory cell layer 30 is bonded to the substrate 25 with the metal bumps 53 and the through electrodes 54 is illustrated in FIG. 1A, other structures may be employed.

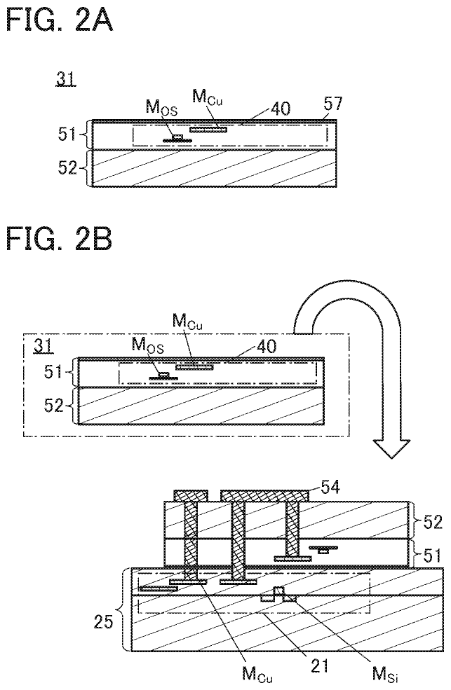

FIG. 2A and FIG. 2B illustrate a structure in which an electrode of a peripheral circuit included in the substrate 25 and an electrode of the element layer 51 included in the memory cell layer 30 are connected by the through electrode 54.

FIG. 2A is a schematic cross-sectional diagram of the memory cell layer 31 that can be used as each of the memory cell layers 31_1 to 31_N in FIG. 1A. FIG. 2A illustrates the element layer 51 provided in contact with the substrate 52. FIG. 2A further illustrates a bonding layer 57 over the element layer 51.

The element layer 51 includes an OS transistor Mos and an electrode M_{Cu}, which are included in the memory cell 40. The electrode M_{Cu} is an electrode connected at the time of forming the through electrode 54. In the case of using copper (Cu) as the electrode M_{Cu}, covering a surface of the electrode with gold (Au) is effective to inhibit the surface from being oxidized at the time of forming the through electrode 54. Note that a structure including a conductor other than copper as the electrode M_{Cu} is also possible.

As the bonding layer 57, silicon oxide (SiOₓ), which enables formation of a bond between a hydroxyl group on the bonding layer 57 and a hydroxyl group on the surface of the substrate 25 as well as forming a planar bonding plane with the substrate 25, is suitable, for example. Silicon oxide (SiOₓ) is preferred to silicon nitride (SiN) or the like because of being capable of forming a more planar surface. In the case where a layer formed on the surface of the substrate 25 and the bonding layer 57 are each formed of a layer containing silicon oxide (SiOₓ) and the planarity of the silicon oxide is increased, a hydroxyl group (OH group) on the surface of the silicon oxide formed on the surface of the substrate 25 and a hydroxyl group (OH group) on the surface of the silicon oxide of the bonding layer 57 are bonded to each other owing to the van der Waals force, and heat treatment performed later can generate a Si—O—Si bond and an H₂O molecule.

FIG. 2B is a schematic cross-sectional diagram illustrating a case where the memory cell layer 31 in FIG. 2A is bonded to the substrate 25 in a face-down manner (face down bonding). The substrate 25 includes a Si transistor Mₛᵢ and an electrode M_{Cu}, which are included in the peripheral circuit 21. The through electrode 54 provided in the element layer 51 and the substrate is provided so as to connect the electrode M_{Cu} included in the memory cell 40 and the electrode M_{Cu} included in the peripheral circuit 21 to each other.

By the increased planarity of the bonding layer 57 or the like, bonding between the substrate 25 and the memory cell layer 31 is possible in a range with an upper limit of 350° C. to 450° C. without exposure to high temperatures of 1000° C. or higher. That is, bonding between the substrate 25 and the memory cell layer 31 is possible without exposure to high temperatures. Accordingly, variations in electrical characteristics of the OS transistor Mos caused by exposing the element layer 51 to high temperatures can be inhibited. In addition, since the Si transistor is not exposed to high temperatures in bonding between the substrate 25 and the memory cell layer 31, using a copper wiring is possible.

The above-described bonding between the substrate 25 and the memory cell layer 31 is effective not only in bonding the memory cell layer 31 including an OS transistor but also in bonding a memory cell layer including a Si transistor. Since the upper limit of the range of the temperature in bonding can be 350° C. to 450° C., a structure in which memory cell layers including Si transistors and memory cell layers including OS transistors are alternately bonded can be employed.

One embodiment of the present invention uses an OS transistor with an extremely low off-state current as a transistor provided in each element layer. Accordingly, the frequency of refresh of data retained in memory cells can be reduced, and a semiconductor device with reduced power consumption can be obtained. OS transistors can be stacked and can be manufactured in the perpendicular direction by employing the same manufacturing process repeatedly, whereby manufacturing cost can be reduced. Furthermore, in one embodiment of the present invention, the memory density can be increased by arranging the transistors included in the memory cells in not a plane direction but the perpendicular direction, whereby the device can be downsized. Moreover, since an OS transistor has smaller variations in electrical characteristics than a Si transistor even in a high-temperature environment, the semiconductor device can function as a highly reliable memory device in which stacked and integrated transistors have small variations in electrical characteristics.

The structure described in this embodiment can be used in an appropriate combination with the structures described in the other embodiments and the like.

### Embodiment 2

In this embodiment, an example of the structure of a semiconductor device of one embodiment of the present invention, which is different from the structure in Embodiment 1, will be described. The above description can be referred to for portions similar to those in Embodiment 1, and detailed description of the portions is omitted.

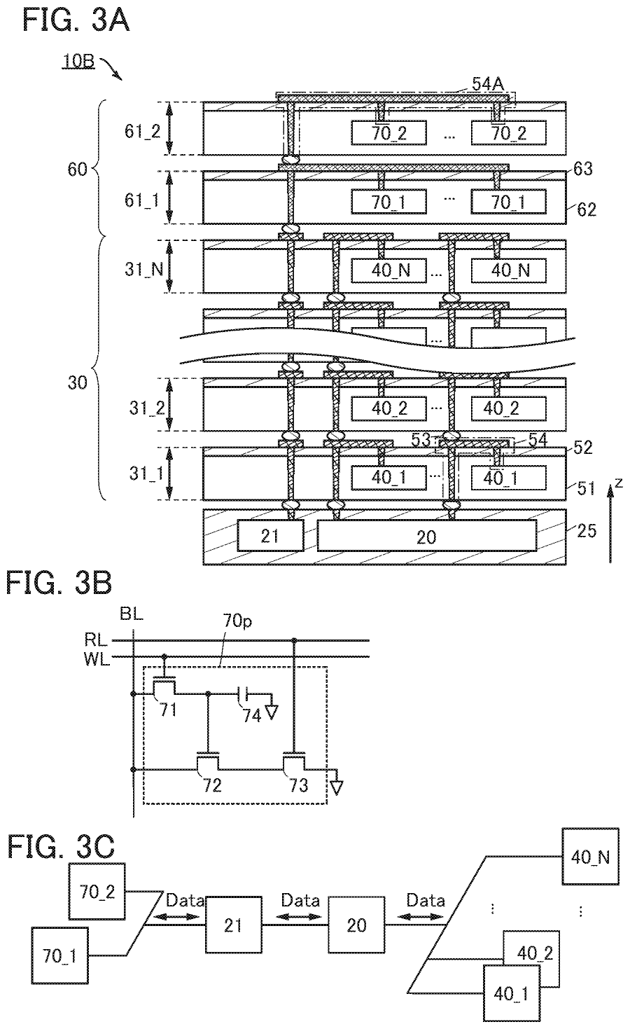

FIG. 3A is a schematic cross-sectional diagram of a semiconductor device described in this embodiment. A semiconductor device 10B illustrated in FIG. 3A includes another memory cell layer 60 in a layer over the memory cell layer 30 described in Embodiment 1. The other memory cell layer 60 includes memory cell layers 61_1 and 61_N ((memory cell layers 61_1 and 61_2 are illustrated) in which memory cells 70_1 and 70_N (memory cells 70_1 and 70_2 are illustrated) are provided, for example. In FIG. 3A, the substrate 25 includes the peripheral circuit in addition to the peripheral circuit 20.

The peripheral circuit 21 includes circuits for outputting signals for driving the memory cells 70_1 to 70_N, such as a row driver and a column driver. The peripheral circuit 21 preferably drives the memory cells 70_1 to 70_N at high speed. Thus, the peripheral circuit 21 preferably includes a transistor that operates at high speed. The transistor included in the peripheral circuit 21 is preferably a transistor that includes silicon in a channel formation region (a Si transistor) with high field-effect mobility. Note that the peripheral circuit 21 may be referred to as a control circuit, a driver circuit, or a circuit.

The memory cell layers 61_1 to 61_N each include an element layer 62 and a substrate 63. The memory cell layers 61_1 to 61_N are provided to be stacked in a direction perpendicular or substantially perpendicular to the surface of the substrate 25. With this structure, the number of memory cells 70_1 to 70_N provided per unit area can be increased, whereby the memory density can be increased. In the schematic cross-sectional diagram illustrated in FIG. 3A, the direction perpendicular or substantially perpendicular to the surface of the substrate 25 is defined as a z-axis direction in order to explain the position of components.

Part of the through electrodes 54 provided in the memory cell layers 31_1 to 31_N, through electrodes 54A provided in the memory cell layers 61_1 to 61_N, and part of the metal bumps 53 provided between the through electrodes 54A and the through electrodes 54 function as a wiring for electrically connecting the peripheral circuit 21 and the memory cells 70_1 to 70_N. Since the through electrodes 54, the through electrodes 54A, and the metal bumps 53 functioning as the wiring can be provided in the direction perpendicular or substantially perpendicular to the surface of the substrate 25, the distance between the peripheral circuit 21 and the memory cells 70_1 to 70_N can be shortened. The through electrodes 54, the through electrodes 54A, and the metal bumps 53 can function as a bit line for writing or reading data to/from the memory cells 70_1 to 70_N or a word line for bringing the memory cells 70_1 to 70_N into a selected state.

A circuit structure of a memory cell that is applicable to the memory cells 70_1 to 70_N is illustrated in FIG. 3B. A memory circuit 70p illustrated in FIG. 3B includes transistors 71 to and a capacitor 74. One of a source and a drain of the transistor 71 is connected to a wiring BL. A gate of the transistor 71 is connected to a wiring WL. The other of the source and the drain of the transistor 71 is connected to a gate of the transistor 72 and the capacitor 74. One of a source and a drain of the transistor 72 is connected to the wiring BL. The other of the source and the drain of the transistor 72 is connected to one of a source and a drain of the transistor 73. A gate of the transistor 73 is connected to a wiring RL through which a read signal is supplied.

Although the wiring BL that is used for both writing and reading of data is illustrated in FIG. 3B, different wirings may be used as the wiring BL. For example, a structure in which the transistor 71 and the transistor 72 are connected to different wirings BL (a wiring RBL for reading and a wiring WBL for writing) may be used. Although the memory circuit including three transistors is illustrated in FIG. 3B, a memory circuit with a structure omitting the transistor 73 and including two transistors may be used.

The transistor 71 is preferably an OS transistor. The off-state current of an OS transistor is extremely low. Accordingly, electric charge corresponding to data written to the memory cells 70_1 to 70_N can be retained in the gate of the transistor 72 and the capacitor 74 for a long time. In other words, data once written to the memory cells 70_1 to 70_N can be retained for a long time. This means the memory circuit 70p has a nonvolatile property. In this specification and the like, a memory cell including the memory circuit 70p including an OS transistor is referred to as a NOSRAM (Nonvolatile Oxide Semiconductor Random Access Memory). In the NOSRAM, data is rewritten by charge and discharge of the capacitor; therefore, there is theoretically no limit on rewrite cycles, and data can be written and read with low energy. In addition, the circuit structure of the memory cell is simple, and thus the capacity can be easily increased. Thus, the NOSRAM is a memory with large capacity, low power consumption, and high rewrite endurance.

In the case where data in the NOSRAM is multilevel data with three or more levels, data capacity per memory cell can be larger than that of a DOSRAM. Furthermore, the NOSRAM can nondestructively read the written data and thus is suitable for long-time data retention. In contrast, the DOSRAM destructively reads written data and thus is suitable for a memory hierarchy level with high write and read frequency. Therefore, the memory cell layer 30 including the DOSRAM memory cells is preferably provided closer to the substrate 25 than the memory cell layer 60 including the NOSRAM memory cells is. That is, the memory cell layer 30 is preferably provided between the substrate 25 and the memory cell layer 60.

Data retained in a memory cell can be appropriately transferred to the NOSRAM according to the usage conditions. For example, as illustrated in FIG. 3C, the data signal Data retained in the memory cells 40_1 to 40_N can be transferred to the memory cells 70_1 and 70_2 through the peripheral circuit 20 and the peripheral circuit 21.

One embodiment of the present invention uses an OS transistor with an extremely low off-state current as a transistor provided in each element layer. Accordingly, the frequency of refresh of data retained in memory cells can be reduced, and a semiconductor device with reduced power consumption can be obtained. OS transistors can be stacked and can be manufactured in the perpendicular direction by employing the same manufacturing process repeatedly, whereby manufacturing cost can be reduced. Furthermore, in one embodiment of the present invention, the memory density can be increased by arranging the transistors included in the memory cells in not a plane direction but the perpendicular direction, whereby the device can be downsized. Moreover, since an OS transistor has smaller variations in electrical characteristics than a Si transistor even in a high-temperature environment, the semiconductor device can function as a highly reliable memory device in which stacked and integrated transistors have small variations in electrical characteristics.

The structure described in this embodiment can be used in an appropriate combination with the structures described in the other embodiments and the like.

### Embodiment 3

In this embodiment, an example of the structure of a semiconductor device of one embodiment of the present invention, which is different from the structures in Embodiments 1 and 2, will be described. The above description can be referred to for portions similar to those in Embodiments 1 and 2, and detailed description of the portions is omitted.

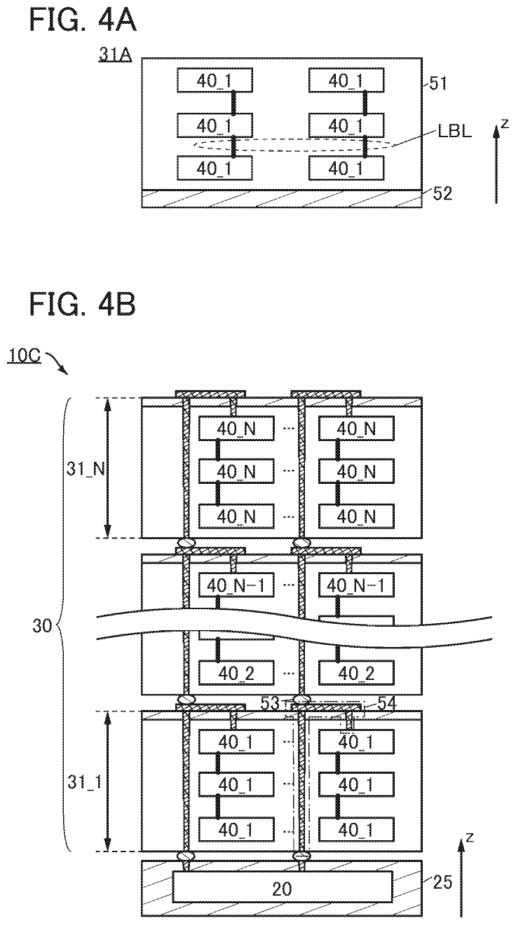

FIG. 4A is a schematic cross-sectional diagram of a memory cell layer 31A that can be used in the semiconductor device of one embodiment of the present invention. The memory cell layer 31A illustrated in FIG. 4A has a structure in which a plurality of the memory cells 40_1 are stacked in the z-axis direction in the element layer 51 of the memory cell layer 31_1 described in Embodiment 1 or 2. Although the memory cell layer 31_1 is illustrated in FIG. 4A, the same applies to the memory cell layer 31_2 to the memory cell layer 31_N. Note that a wiring connecting the memory cells 40_1 to each other in the element layer 51 may be referred to as a wiring LBL (local bit line). Unlike the through electrodes 54 described in the above embodiments, the wiring LBL is a wiring formed of interlayer conductors in the element layer 51.

FIG. 4B is a schematic cross-sectional diagram of the semiconductor device described in this embodiment. A semiconductor device 10C illustrated in FIG. 4B has a structure in which the structure of the memory cell layer 31A illustrated in FIG. 4A is applied to each of the memory cell layers 31_1 to 31_N. With this structure, the number of memory cells per unit area can be increased and the number of metal bumps 53 and through electrodes 54 can be reduced, whereby manufacturing cost can be reduced and the memory density can be increased.

One embodiment of the present invention uses an OS transistor with an extremely low off-state current as a transistor provided in each element layer. Accordingly, the frequency of refresh of data retained in memory cells can be reduced, and a semiconductor device with reduced power consumption can be obtained. OS transistors can be stacked and can be manufactured in the perpendicular direction by employing the same manufacturing process repeatedly, whereby manufacturing cost can be reduced. Furthermore, in one embodiment of the present invention, the memory density can be increased by arranging the transistors included in the memory cells in not a plane direction but the perpendicular direction, whereby the device can be downsized. Moreover, since an OS transistor has smaller variations in electrical characteristics than a Si transistor even in a high-temperature environment, the semiconductor device can function as a highly reliable memory device in which stacked and integrated transistors have small variations in electrical characteristics.

The structure described in this embodiment can be used in an appropriate combination with the structures described in the other embodiments and the like.

### Embodiment 4

In this embodiment, an example of the structure of a semiconductor device of one embodiment of the present invention, which is different from the structures in Embodiments 1 to 3, will be described. The above description can be referred to for portions similar to those in Embodiments 1 to 3, and detailed description of the portions is omitted.

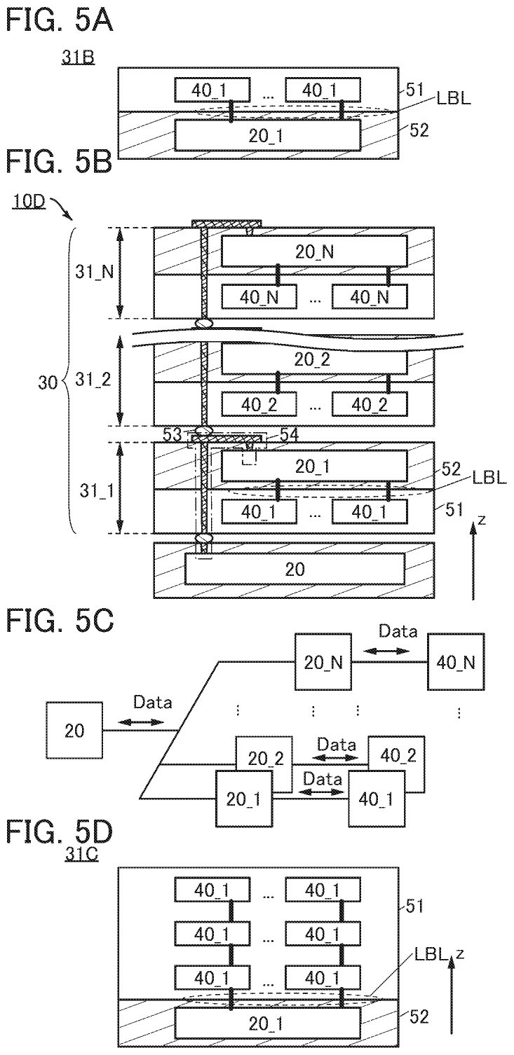

FIG. 5A is a schematic cross-sectional diagram of a memory cell layer 31B that can be used in the semiconductor device of one embodiment of the present invention. The memory cell layer 31B illustrated in FIG. 5A has a structure in which the peripheral circuit 20_1 (peripheral circuits 20_1 to 20_N) that can execute part of the function of the peripheral circuit 20 is provided in the substrate 52 in the memory cell layer 31_1 (the memory cell layers 31_1 to 31_N) described in Embodiments 1 to 3. Although FIG. 5A illustrates the example in which the structure is applied to the memory cell layer 31_1, the same applies to the memory cell layer 31_2 to the memory cell layer 31_N. Note that a wiring connecting the peripheral circuit 20_1 provided in the substrate 52 and the memory cell 40_1 in the element layer 51 to each other may be referred to as a wiring LBL (local bit line). Like the wiring LBL described above in Embodiment 3, the wiring LBL is a wiring formed of an interlayer conductor between the substrate 52 and the element layer 51. The peripheral circuit 20_1 (the peripheral circuits 20_1 to 20_N) can be a circuit such as a sense amplifier having a function of amplifying a signal, in order to perform the function of part of the peripheral circuit 20, for example, writing or reading of data.

FIG. 5B is a schematic cross-sectional diagram of the semiconductor device described in this embodiment. A semiconductor device 10D illustrated in FIG. 5B has a structure in which the structure of the memory cell layer 31B illustrated in FIG. 5A is applied to each of the memory cell layers 31_1 to 31_N.

In the case where the number of the memory cell layers 31_1 to 31_N is 100 or more, for example, the distance between the uppermost memory cell layer and the peripheral circuit 20 can be short. In this case, the function of amplifying data in the peripheral circuits 20_1 to 20_N enables data input and output between the uppermost memory cell layer and the peripheral circuit 20. For example, as illustrated in FIG. 5C, with a structure in which the data signal Data retained in the memory cells 40_1 to 40_N is amplified in the peripheral circuits 20_1 to 20_N, data input and output between the memory cells 40_1 to 40_N and the peripheral circuit 20 is possible without a significant difference in data writing speed and data reading speed.

The memory cell layer 31B illustrated in FIG. 5A may have a structure in which a plurality of the memory cells 40_1 are stacked in the z-axis direction in the element layer 51. In a memory cell layer 31C illustrated in FIG. 5D, the peripheral circuit 20_1 is provided in the substrate 52, and the plurality of memory cells 40_1 are stacked in the z-axis direction in the element layer 51.

Although the structure in which the memory cell layer 31B is bonded to the substrate 25 with the metal bumps 53 and the through electrodes 54 is illustrated in FIG. 5(B), other structures may be employed.

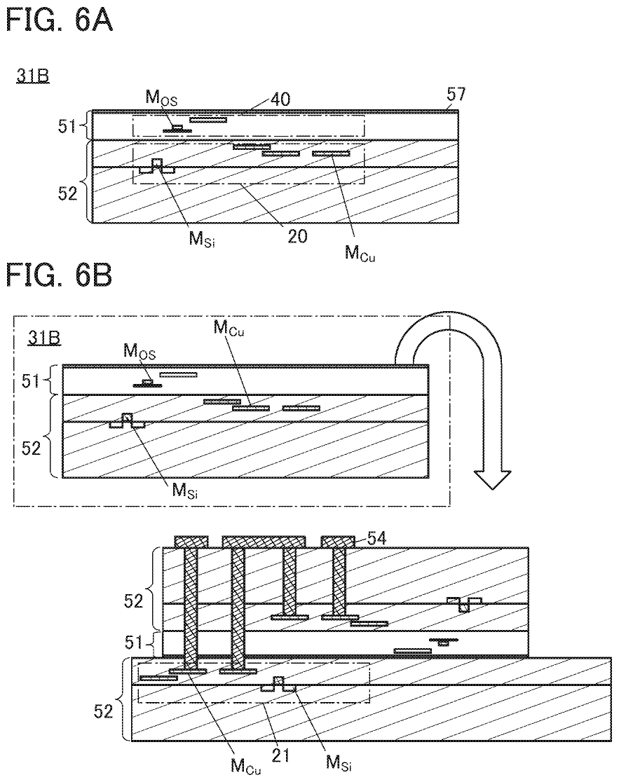

FIG. 6A and FIG. 6B illustrate a structure in which an electrode of the peripheral circuit included in the substrate 25 and an electrode of the substrate 52 included in the memory cell layer 31B are connected by the through electrode 54.

FIG. 6A is a schematic cross-sectional diagram of the memory cell layer 31B that can be used as each of the memory cell layers 31_1 to 31_N in FIG. 5A. FIG. 6A illustrates the element layer 51 provided in contact with the substrate 52. FIG. 6A further illustrates the bonding layer 57 over the element layer 51.

The element layer 51 includes the OS transistor Mos which is included in the memory cell 40.

The peripheral circuit 20 that is applicable to the peripheral circuits 20_1 to 20_N includes the Si transistor Mₛᵢ and the electrode M_{Cu}. The electrode Mc, is an electrode connected at the time of forming the through electrode 54. In the case of using copper (Cu) as the electrode Wu, covering a surface of the electrode with gold (Au) is effective to inhibit the surface from being oxidized at the time of forming the through electrode 54. Note that a structure including a conductor other than copper as the electrode M_{Cu} is also possible.

As the bonding layer 57, silicon oxide (SiOₓ), which enables formation of a bond between a hydroxyl group on the bonding layer 57 and a hydroxyl group on the surface of the substrate 25 as well as forming a planar bonding plane with the substrate 25, is suitable, for example.

FIG. 6B is a schematic cross-sectional diagram illustrating a case where the memory cell layer 31B in FIG. 6A is bonded to the substrate 25 in a face-down manner (face down bonding). The substrate 25 includes the Si transistor Mₛᵢ and the electrode M_{Cu}, which are included in the peripheral circuit 21. The through electrode 54 provided in the element layer 51 and the substrate is provided so as to connect the electrode M_{Cu} included in the peripheral circuit 20 and the electrode M_{Cu} included in the peripheral circuit 21 to each other.

By the increased planarity of the bonding layer 57 or the like, bonding between the substrate 25 and the memory cell layer 31B is possible in a range with an upper limit of 350° C. to 450° C. without exposure to high temperatures of 1000° C. or higher. That is, bonding between the substrate 25 and the memory cell layer 31B is possible without exposure to high temperatures. Accordingly, variations in electrical characteristics of the OS transistor Mos caused by exposing the element layer 51 to high temperatures can be inhibited. In addition, since the Si transistor is not exposed to high temperatures in bonding between the substrate 25 and the memory cell layer 31B, using a copper wiring is possible.

The above-described bonding between the substrate 25 and the memory cell layer 31B is effective not only in bonding the memory cell layer 31B including an OS transistor and a Si transistor but also in bonding a memory cell layer including a Si transistor, e.g., a memory cell layer including a DRAM memory cell or the like. Since the upper limit of the range of the temperature in bonding can be 350° C. to 450° C., a structure in which memory cell layers including Si transistors and memory cell layers including OS transistors and Si transistors are alternately bonded can be employed.

One embodiment of the present invention uses an OS transistor with an extremely low off-state current as a transistor provided in each element layer. Accordingly, the frequency of refresh of data retained in memory cells can be reduced, and a semiconductor device with reduced power consumption can be obtained. OS transistors can be stacked and can be manufactured in the perpendicular direction by employing the same manufacturing process repeatedly, whereby manufacturing cost can be reduced. Furthermore, in one embodiment of the present invention, the memory density can be increased by arranging the transistors included in the memory cells in not a plane direction but the perpendicular direction, whereby the device can be downsized. Moreover, since an OS transistor has smaller variations in electrical characteristics than a Si transistor even in a high-temperature environment, the semiconductor device can function as a highly reliable memory device in which stacked and integrated transistors have small variations in electrical characteristics.

The structure described in this embodiment can be used in an appropriate combination with the structures described in the other embodiments and the like.

### Embodiment 5

In this embodiment, an example of the structure of a semiconductor device of one embodiment of the present invention, which is different from the structures in Embodiments 1 to 4, will be described. The above description can be referred to for portions similar to those in Embodiments 1 to 4, and detailed description of the portions is omitted.

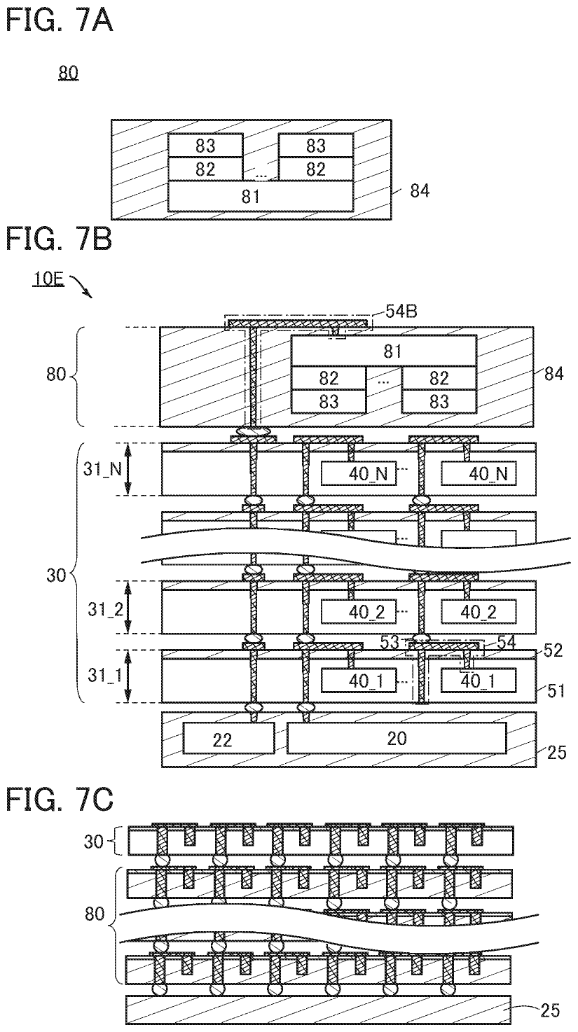

FIG. 7A is a schematic cross-sectional view of a semiconductor device described in this embodiment. A memory cell layer 80 illustrated in FIG. 7A has a structure in which a DRAM (Dynamic Random Access Memory) including Si transistors provided in a substrate 84 is provided. In FIG. 7A, the substrate 84 includes a peripheral circuit 81, a transistor 82, and a capacitor 83. The peripheral circuit 81 is referred to as a control circuit, a driver circuit, or a circuit, in some cases. The transistor 82 and the capacitor 83 correspond to elements constituting a memory cell of the DRAM.

FIG. 7B is a schematic cross-sectional view of a semiconductor device described in this embodiment. A semiconductor device 10E illustrated in FIG. 7B includes the memory cell layer illustrated in FIG. 7A over the memory cell layer 30 described in Embodiment 1. Although the illustrated memory cell layer 80 is a single layer, the memory cell layer 80 may be a multilayer. In FIG. 7B, the substrate 25 includes a peripheral circuit 22 in addition to the peripheral circuit 20.

Note that the peripheral circuit 22 includes circuits, such as a row driver and a column driver, for outputting signals for driving the memory cell of the DRAM which is included in the memory cell layer 80 and formed of the transistor 82 and the capacitor 83. The peripheral circuit 22 preferably includes a transistor that operates at high speed. The transistor included in the peripheral circuit 22 is preferably a transistor that includes silicon in a channel formation region (a Si transistor) with high field-effect mobility. The peripheral circuit 22 is referred to as a control circuit, a driver circuit, or a circuit, in some cases.

The through electrodes 54 provided in the memory cell layers 31_1 to 31_N, part of a through electrode 54B provided in the memory cell layer 80, and part of the metal bumps 53 provided between the through electrode 54B and the through electrodes 54 function as a wiring for electrically connecting the peripheral circuit 22 and the memory cell of the DRAM which is formed of the transistor 82 and the capacitor 83. Since the through electrodes 54, the through electrode 54B, and the metal bumps 53 functioning as the wiring can be provided in the direction perpendicular or substantially perpendicular to the surface of the substrate 25, the distance between the peripheral circuit 22 and the memory cell of the DRAM which is formed of the transistor 82 and the capacitor 83 can be shortened. The through electrodes 54, the through electrode 54B, and the metal bumps 53 can function as a bit line for writing or reading data to/from the memory cell of the DRAM which is formed of the transistor 82 and the capacitor 83 or a word line for bringing the memory cell of the DRAM which is formed of the transistor 82 and the capacitor 83 into a selected state.

Although FIG. 7B illustrates a structure in which the memory cell layer 80 including the DRAM memory cells is bonded to the memory cell layer 30 including the DOSRAM memory cells which is bonded to the substrate 25, another structure may be employed. In FIG. 7C, the memory cell layer 30 including the DOSRAM memory cells can be bonded to and over the memory cell layer 80 including a plurality of layers of DRAM memory cells bonded to the substrate 25. As the memory cell layer provided over the memory cell layer 80, a memory cell layer including NOSRAM memory cells may be used instead of the memory cell layer including the DOSRAM memory cells; or stacked memory cell layers formed of a memory cell layer including NOSRAM memory cells and a memory cell layer including DOSRAM memory cells may be provided over the memory cell layer 30.

A DRAM including a Si transistor has higher data transfer speed than a DOSRAM including an OS transistor. On the other hand, the DOSRAM including an OS transistor has a lower data refresh frequency than the DRAM including a Si transistor and is effective in reducing power consumption. To achieve both high data transfer speed and low power consumption in the semiconductor device 10E including the DRAM described in this embodiment, a structure of switching the state of the memory cell where data is retained among a plurality of states in accordance with the data access state is effective.

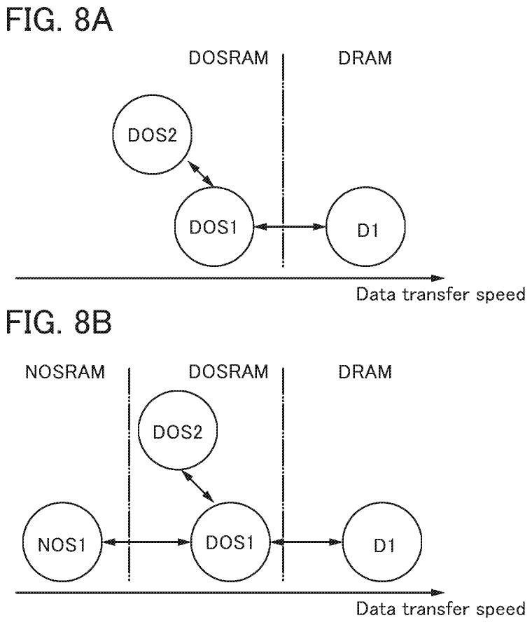

For example, FIG. 8A illustrates a mode D1 where data is retained in the DRAM and modes DOS1 and DOS2 where data is retained in the DOSRAM. The modes DOS1 and DOS2 are modes with different data refresh frequencies; the power consumption in the mode DOS2 with a lower data refresh frequency can be lower than that in the mode DOS1. Switching among the modes illustrated in FIG. 8A in accordance with the data access state allows both high data transfer speed and low power consumption.

Furthermore, FIG. 8B illustrates a mode NOS1 where data is retained in a NOSRAM in addition to the mode D1 where data is retained in the DRAM and the modes DOS1 and DOS2 where data is retained in the DOSRAM, which are illustrated in FIG. 8A. A memory cell layer including the NOSRAM may be provided over the memory cell layer 30. Since the NOSRAM is capable of nondestructive reading unlike the DOSRAM, a structure of switching to the mode NOS1 where data is retained in the NOSRAM is effective in the case where data is accessed infrequently. Switching among the modes illustrated in FIG. 8B in accordance with the data access state allows both high data transfer speed and low power consumption.

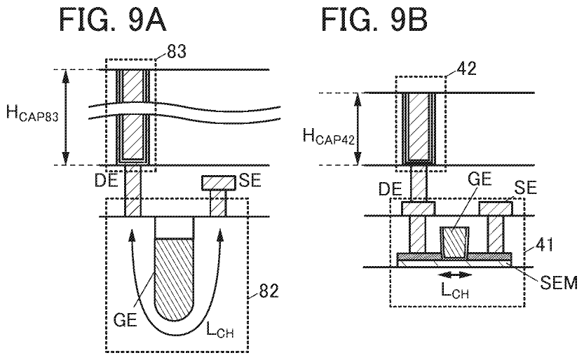

Here, a Si transistor included in a memory cell of the DRAM described with reference to FIG. 8A is illustrated in FIG. 9A. FIG. 9A illustrates a schematic cross-sectional view of the transistor 82 and the capacitor 83. In the transistor 82 illustrated in FIG. 9A, a gate electrode GE embedded in a silicon substrate, a source electrode SE provided on the source side of the transistor 82, and a drain electrode DE provided on the drain side of the transistor 82 are illustrated. As the capacitor 83 provided over the transistor 82, what is called a three-dimensional capacitor provided through formation of a deep hole is illustrated.

FIG. 9B illustrates an OS transistor included in a memory cell of the DOSRAM described with reference to FIG. 1C in Embodiment 1. FIG. 9B illustrates a schematic cross-sectional view of the transistor 41 and the capacitor 42. In the transistor 41 illustrated in FIG. 9B, a gate electrode GE provided in a region overlapping with a semiconductor layer SEM over a substrate, a source electrode SE provided on the source side of the transistor 41, and a drain electrode DE provided on the drain side of the transistor 41 are illustrated. As the capacitor 42 provided over the transistor 41, what is called a three-dimensional capacitor provided through formation of a deep hole is illustrated.

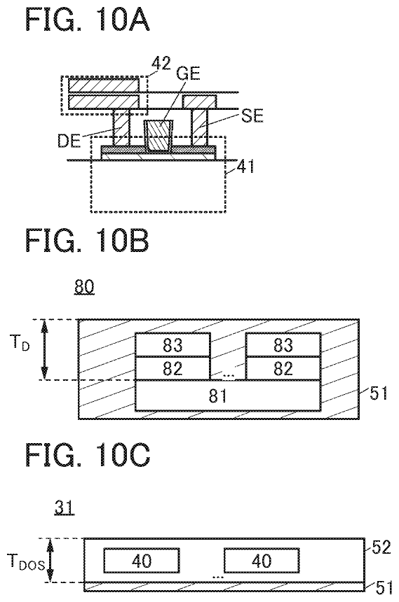

Although the three-dimensional capacitor is illustrated as the capacitor 42 for the OS transistor included in the DOSRAM, another structure may be employed. Since the off-state current of the OS transistor is extremely low, the capacitance of the capacitor can be estimated to be low. Thus, as illustrated in FIG. 10A, a two-dimensional capacitor can also be used.

The Si transistor included in the DRAM has a higher off-state current than the OS transistor. Thus, in order to reduce the off-state current of the Si transistor, the channel length (L_{CH} in FIG. 9A) needs to be long. Therefore, the transistor 82 needs to extend in the z-axis direction and thinning the substrate is difficult. In addition, in order to retain charge, the capacitance of the capacitor 83 needs to be high, which requires a large height of the capacitor 83 (H_{CAP83} in FIG. 9A). Accordingly, in the memory layers including the DRAM including the Si transistor, the film thickness TD in the z-axis direction is large in a portion where the transistor 82 and the capacitor 83 are provided (the memory cell layer 80 in FIG. 10B).

In contrast, the off-state current of the OS transistor included in the DOSRAM is extremely low as described in Embodiment 1. Therefore, lengthening the channel length (L_{CH} in FIG. 9B) by extension in the z-axis direction or the like in order to reduce the off-state current is unnecessary. Accordingly, in the transistor 41, the substrate 52 can be thinned in the z-axis direction. In addition, increasing the height of the capacitor 42 (H_{CAP42} in FIG. 9B) in order to increase the capacitance of the capacitor 42 is unnecessary. Accordingly, in the memory cell layer including the DOSRAM including the OS transistor, the film thickness T_{DOS} of the element layer where the transistor 41 and the capacitor 42 are provided in the z-axis direction can be made small (the memory cell layer in FIG. 10C). Therefore, each of the memory cell layers including the DOSRAM which are stacked and bonded to each other can be thinner than the memory cell layer including the DRAM.

One embodiment of the present invention uses an OS transistor with an extremely low off-state current as a transistor provided in each element layer. Accordingly, the frequency of refresh of data retained in memory cells can be reduced, and a semiconductor device with reduced power consumption can be obtained. OS transistors can be stacked and can be manufactured in the perpendicular direction by employing the same manufacturing process repeatedly, whereby manufacturing cost can be reduced. Furthermore, in one embodiment of the present invention, the memory density can be increased by arranging the transistors included in the memory cells in not a plane direction but the perpendicular direction, whereby the device can be downsized. Moreover, since an OS transistor has smaller variations in electrical characteristics than a Si transistor even in a high-temperature environment, the semiconductor device can function as a highly reliable memory device in which stacked and integrated transistors have small variations in electrical characteristics.

The structure described in this embodiment can be used in an appropriate combination with the structures described in the other embodiments and the like.

### Embodiment 6

In this embodiment, an example of the structure of a semiconductor device of one embodiment of the present invention, which is different from the structures in Embodiments 1 to 5, will be described. The above description can be referred to for portions similar to those in Embodiments 1 to 5, and detailed description of the portions is omitted.

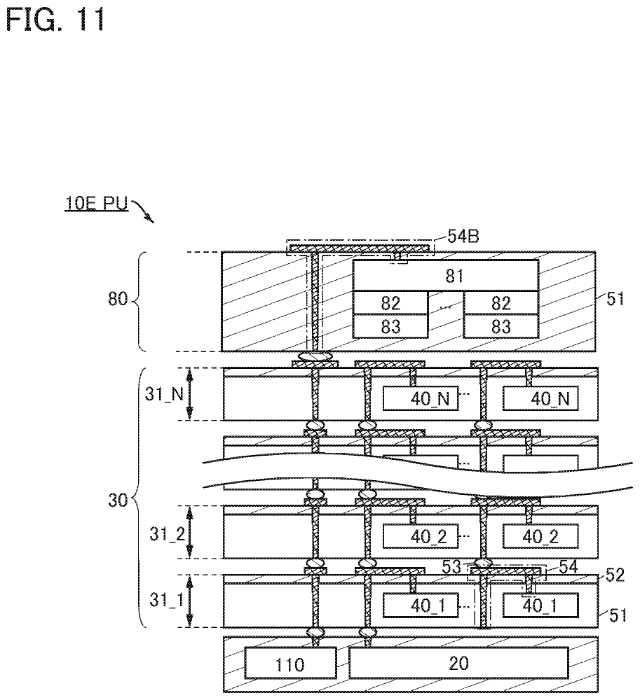

FIG. 11 is a schematic cross-sectional diagram of a semiconductor device described in this embodiment. A semiconductor device 10E_PU illustrated in FIG. 11 has a structure in which the peripheral circuit 22 is replaced by a CPU 110 in the substrate 25 described in Embodiment 5.

Data retained in the CPU 110 can be retained in the memory cells 40_1 to 40_N and the DRAM memory cell formed of the transistor 82 and the capacitor 83. Furthermore, data retained in the CPU 110 can be retained in a memory cell having a circuit structure different from the memory cells 40_1 to 40_N and including an OS transistor.

Since the CPU 110 performs an operation of inputting and outputting a signal at high speed, heat generation caused by the flow of a current is large. In the case of the structure in which a DRAM is bonded to the CPU, data is sometimes hard to retain due to the influence of the heat generation.

As illustrated in FIG. 11, in the structure of this embodiment, the memory cell layer 80 including the DRAM can be provided over the memory cell layer 30 including the memory cells 40_1 to 40_N including OS transistors. Having a large ratio between on-state current and off-state current even under a high-temperature environment, an OS transistor can favorably perform a switching operation. Moreover, the memory cell layer 80 including the DRAM can be provided away from the CPU 110 with the memory cell layer 30 including the memory cells 40_1 to 40_N including OS transistors therebetween. Therefore, the semiconductor device can have properties of both a memory device utilizing an extremely low off-state current and a memory device capable of a high-speed operation and have high reliability with small variations in electrical characteristics of transistors.

Next, a structural example of the CPU 110 will be described. In this embodiment, the CPU 110 including a CPU core capable of power gating will be described.

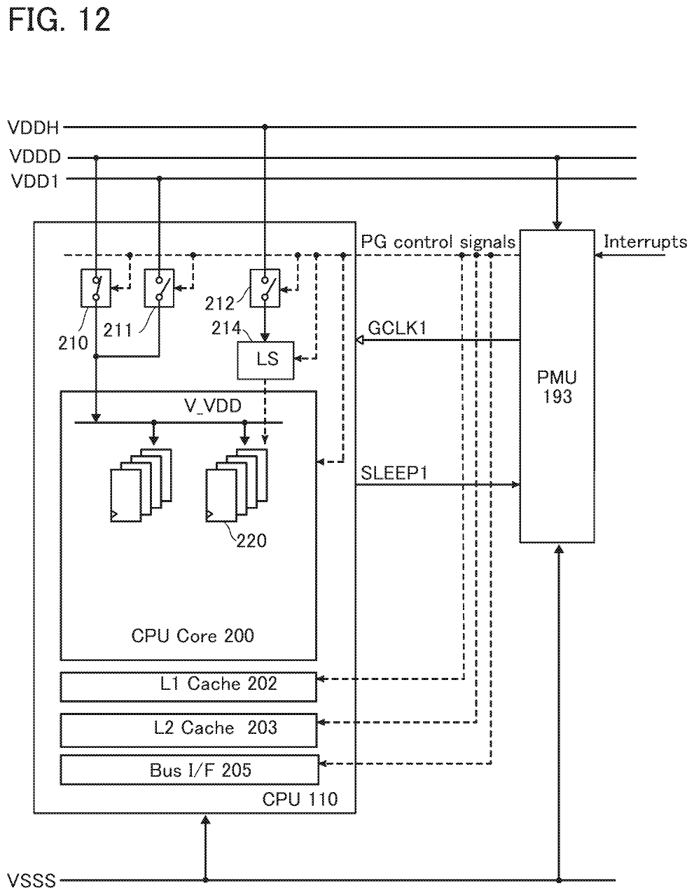

FIG. 12 illustrates a structure example of the CPU 110. The CPU 110 includes the CPU core 200, an L1 (level 1) cache memory device (L1 Cache) 202, an L2 cache memory device (L2 Cache) 203, a bus interface portion (Bus I/F) 205, power switches 210 to 212, and a level shifter (LS) 214. The CPU core 200 includes a flip-flop 220.

Through the bus interface portion 205, the CPU core 200, the L1 cache memory device 202, and the L2 cache memory device 203 are mutually connected to one another.

A PMU 193 generates a clock signal GCLK1 and various PG (power gating) control signals in response to signals such as an interrupt signal (Interrupts) input from the outside and a signal SLEEP1 issued from the CPU 110. The clock signal GCLK1 and the PG control signals are input to the CPU 110. The PG control signals control the power switches 210 to 212 and the flip-flop 220.

The power switches 210 and 211 control the supply of voltages VDDD and VDD1, respectively, to a virtual power supply line V_VDD (hereinafter, referred to as a V_VDD line). The power switch 212 controls the supply of a voltage VDDH to the level shifter (LS) 214. A voltage VSSS is input to the CPU 110 and the PMU 193 not through the power switches. The voltage VDDD is input to the PMU 193 not through the power switches.

The voltages VDDD and VDD1 are drive voltages for a CMOS circuit. The voltage VDD1 is lower than the voltage VDDD and is a drive voltage in a sleep state. The voltage VDDH is a drive voltage for an OS transistor and is higher than the voltage VDDD.

The L1 cache memory device 202, the L2 cache memory device 203, and the bus interface portion 205 each include at least one power domain capable of power gating. The power domain capable of power gating is provided with one or a plurality of power switches. These power switches are controlled by the PG control signals.

The flip-flop 220 is used for a register. The flip-flop 220 is provided with a backup circuit. The flip-flop 220 is described below.

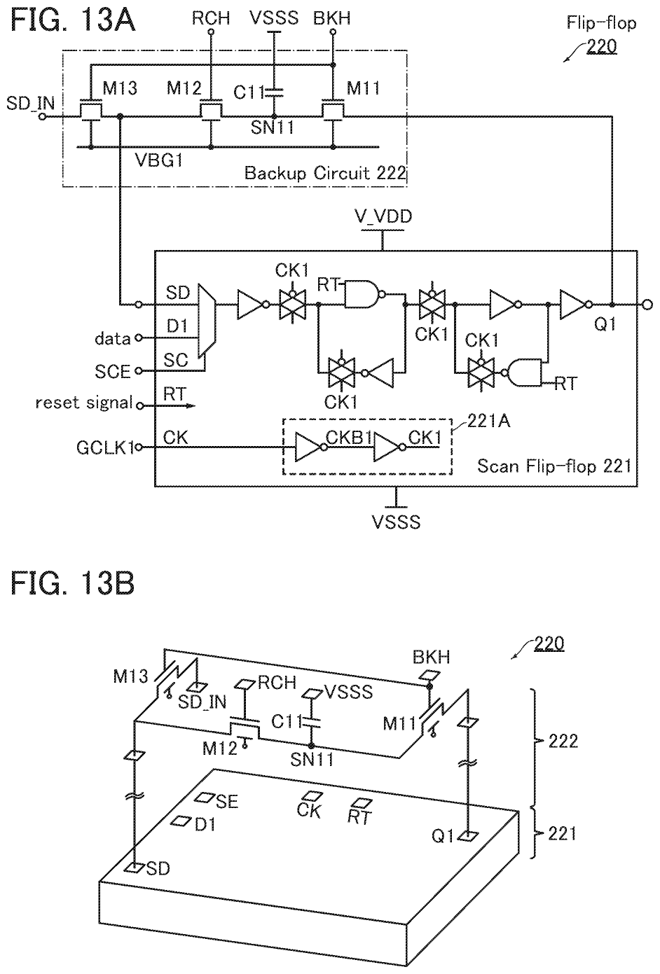

FIG. 13A illustrates a circuit structure example of the flip-flop 220. The flip-flop 220 includes a scan flip-flop 221 and the backup circuit 222. The scan flip-flop 221 can be provided in the substrate 25 in FIG. 11, and the backup circuit 222 can be provided in the same layer as the memory cell layer 30.

The scan flip-flop 221 includes nodes D1, Q1, SD, SE, RT, and CK and a clock buffer circuit 221A.

The node D1 is a data input node, the node Q1 is a data output node, and the node SD is a scan test data input node. The node SC is a signal SCE input node. The node CK is a clock signal GCLK1 input node. The clock signal GCLK1 is input to the clock buffer circuit 221A. Respective analog switches in the scan flip-flop 221 are connected to nodes CK1 and CKB1 of the clock buffer circuit 221A. The node RT is a reset signal input node.

The signal SCE is a scan enable signal, which is generated in the PMU 193. The PMU generates signals BK and RC. The level shifter 214 level-shifts the signals BK and RC to generate signals BKH and RCH. The signal BK is a backup signal and the signal RC is a recovery signal.

The circuit structure of the scan flip-flop 221 is not limited to that in FIG. 13A. A flip-flop prepared in a standard circuit library can be used.

The backup circuit 222 includes nodes SD_IN and SN11, transistors M11 to M13, and a capacitor C11.

The node SD_IN is a scan test data input node and is connected to the node Q1 of the scan flip-flop 221. The node SN11 is a retention node of the backup circuit 222. The capacitor C11 is a storage capacitor for retaining the voltage of the node SN11.

The transistor M11 controls electrical continuity between the node Q1 and the node SN11. The transistor M12 controls electrical continuity between the node SN11 and the node SD. The transistor M13 controls electrical continuity between the node SD_IN and the node SD. The on/off of the transistors M11 and M13 is controlled by the signal BKH, and the on/off of the transistor M12 is controlled by the signal RCH.

The transistors M11 to M13 are OS transistors like the transistors included in the above-described memory cell layer 31. The transistors M11 to M13 have back gates in the illustrated structure. The back gates of the transistors M11 to M13 are connected to a power supply line for supplying a voltage VBG1.

At least the transistors M11 and M12 are preferably OS transistors. Because of an extremely low off-state current, which is a feature of the OS transistor, a decrease in the voltage of the node SN11 can be suppressed and almost no power is consumed to retain data; therefore, the backup circuit 222 has a nonvolatile characteristic. Data is rewritten by charge and discharge of the capacitor C11; hence, there is theoretically no limitation on rewrite cycles of the backup circuit 222, and data can be written and read out with low energy.

It is significantly favorable that all of the transistors in the backup circuit 222 are OS transistors. As illustrated in FIG. 13B, the backup circuit 222 can be stacked on the scan flip-flop 221 configured with a silicon CMOS circuit.

The number of elements in the backup circuit 222 is much smaller than the number of elements in the scan flip-flop 221; thus, there is no need to change the circuit structure and layout of the scan flip-flop 221 in order to stack the backup circuit 222. That is, the backup circuit 222 is a backup circuit that has very broad utility. In addition, the backup circuit 222 can be provided in a region where the scan flip-flop 221 is formed; thus, even when the backup circuit 222 is incorporated, the area overhead of the flip-flop 220 can be zero. Thus, when the backup circuit 222 is provided in the flip-flop 220, power gating of the CPU core 200 is possible. The power gating of the CPU core 200 is enabled with high efficiency owing to little energy necessary for the power gating.

When the backup circuit 222 is provided, parasitic capacitance due to the transistor Mi i is added to the node Q1. However, the parasitic capacitance is lower than parasitic capacitance due to a logic circuit connected to the node Q1; thus, there is no influence on the operation of the scan flip-flop 221. That is, even when the backup circuit 222 is provided, the performance of the flip-flop 220 does not substantially decrease.

The CPU core 200 can be set to a clock gating state, a power gating state, or a resting state as a low power consumption state. The PMU 193 selects the low power consumption mode of the CPU core 200 on the basis of the interrupt signal, the signal SLEEP1, and the like. For example, in the case of transition from a normal operation state to a clock gating state, the PMU 193 stops generation of the clock signal GCLK1.

For example, in the case of transition from a normal operation state to a resting state, the PMU 193 performs voltage and/or frequency scaling. For example, when the voltage scaling is performed, the PMU 193 turns off the power switch 210 and turns on the power switch 211 to input the voltage VDD1 to the CPU core 200. The voltage VDD1 is a voltage at which data in the scan flip-flop 221 is not lost. When the frequency scaling is performed, the PMU 193 reduces the frequency of the clock signal GCLK1.

In the case where the CPU core 200 transitions from a normal operation state to a power gating state, data in the scan flip-flop 221 is backed up to the backup circuit 222. When the CPU core 200 is returned from the power gating state to the normal operation state, recovery operation of data in the backup circuit 222 to the scan flip-flop 221 is performed.

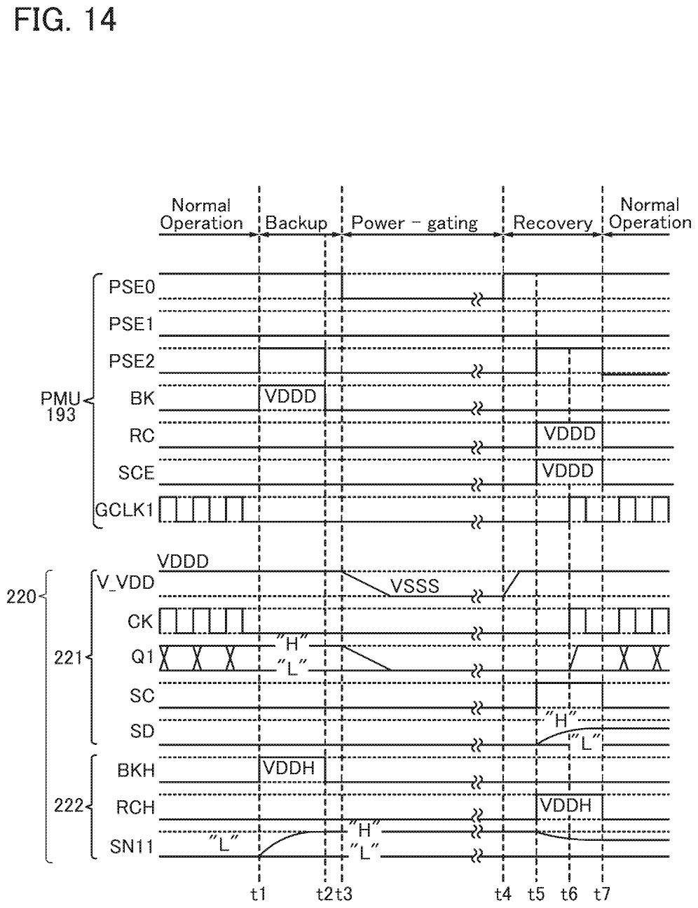

FIG. 14 shows an example of the power gating sequence of the CPU core 200. Note that in FIGS. 14, t1 to t7 represent the time. Signals PSE0 to PSE2 are control signals of the power switches 210 to 212, which are generated in the PMU 193. When the signal PSE0 is at “H”/“L”, the power switch 210 is on/off. The same applies to the signals PSE1 and PSE2.

Before Time t1, a normal operation is performed. The power switch 210 is on, and the voltage VDDD is input to the CPU core 200. The scan flip-flop 221 performs the normal operation. At this time, the level shifter 214 does not need to be operated; thus, the power switch 212 is off and the signals SCE, BK, and RC are each at “L”. The node SC is at “L”; thus, the scan flip-flop 221 stores data in the node D1. Note that in the example of FIG. 14, the node SN11 of the backup circuit 222 is at “L” at Time t1.

A backup operation is described. At Time t1 of operation, the PMU 193 stops the clock signal GCLK1 and sets the signals PSE2 and BK at “H”. The level shifter 214 becomes active and outputs the signal BKH at “H” to the backup circuit 222.

The transistor M11 in the backup circuit 222 is turned on, and data in the node Q1 of the scan flip-flop 221 is written to the node SN11 of the backup circuit 222. When the node Q1 of the scan flip-flop 221 is at “L”, the node SN11 remains at “L”, whereas when the node Q1 is at “H”, the node SN11 becomes “H”.

The PMU 193 sets the signals PSE2 and BK at “L” at Time t2 and sets the signal PSE0 at “L at Time t3. The state of the CPU core 200 transitions to a power gating state at Time t3. Note that at the timing when the signal BK falls, the signal PSE0 may fall.

A power-gating operation is described. When the signal PSE0 is set at “L, data in the node Q1 is lost because the voltage of the V_VDD line decreases. The node SN11 retains data that is stored in the node Q1 at Time t3.

A recovery operation is described. When the PMU 193 sets the signal PSE0 at “H” at Time t4, the power gating state transitions to a recovery state. Charge of the V_VDD line starts, and the PMU 193 sets the signals PSE2, RC, and SCE at “H” in a state where the voltage of the V_VDD line becomes VDDD (at Time t5).

The transistor M12 is turned on, and electric charge in the capacitor C11 is distributed to the node SN11 and the node SD. When the node SN11 is at “H”, the voltage of the node SD increases. The node SC is at “H”; thus, data in the node SC is written to a latch circuit on the input side of the scan flip-flop 221. When the clock signal GCLK1 is input to the node CK at Time t6, data in the latch circuit on the input side is written to the node Q1. That is, data in the node SN11 is written to the node Q1.

When the PMU 193 sets the signals PSE2, SCE, and RC at “L” at Time t7, the recovery operation is terminated.

The backup circuit 222 using an OS transistor is extremely suitable for normally-off computing because both dynamic power consumption and static low power consumption are low. Note that the CPU 110 including the CPU core 200 including the backup circuit 222 using an OS transistor can be referred to as NoffCPU (registered trademark). The NoffCPU includes a nonvolatile memory, and power supply can be stopped during the time when operation is not needed. Even when the flip-flop 220 is mounted, it is possible that a decrease in the performance and an increase in the dynamic power of the CPU core 200 hardly occur.

Note that the CPU core 200 may include a plurality of power domains capable of power gating. In the plurality of power domains, one or a plurality of power switches for controlling voltage input are provided. In addition, the CPU core 200 may include one or a plurality of power domains where power gating is not performed. For example, the power domain where power gating is not performed may be provided with a power gating control circuit for controlling the flip-flop 220 and the power switches 210 to 212.

Note that the usage of the flip-flop 220 is not limited to the CPU 110. In the CPU 110, the flip-flop 220 can be used as the register provided in a power domain capable of power gating.

The structure described in this embodiment can be used in an appropriate combination with the structures described in the other embodiments and the like.

### Embodiment 7

In this embodiment, an example of the structure of a semiconductor device of one embodiment of the present invention, which is different from the structures in Embodiments 1 to 5, will be described. The above description can be referred to for portions similar to those in Embodiments 1 to 5, and detailed description of the portions is omitted.

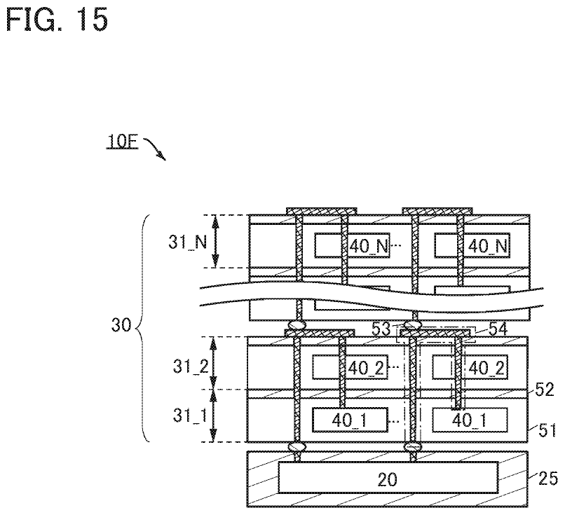

FIG. 15 is a schematic cross-sectional diagram of the semiconductor device described in this embodiment. A semiconductor device 10F illustrated in FIG. 15 has a structure in which the through electrode 54 is provided under the state where some of the memory cell layers 31_1 to N illustrated in FIG. 1A overlap with each other. That is, in the semiconductor device 10F illustrated in FIG. 15, the memory cell 40_1 and the memory cell 40_2 included in the memory cell layer 31_1 and the memory cell layer 31_2 are connected by the through electrode 54 not via the metal bump 53. With this structure, the number of memory cells per unit area can be increased and the number of metal bumps 53 and through electrodes 54 can be reduced, whereby manufacturing cost can be reduced and the memory density can be increased.

One embodiment of the present invention uses an OS transistor with an extremely low off-state current as a transistor provided in each element layer. Accordingly, the frequency of refresh of data retained in memory cells can be reduced, and a semiconductor device with reduced power consumption can be obtained. OS transistors can be stacked and can be manufactured in the perpendicular direction by employing the same manufacturing process repeatedly, whereby manufacturing cost can be reduced. Furthermore, in one embodiment of the present invention, the memory density can be increased by arranging the transistors included in the memory cells in not a plane direction but the perpendicular direction, whereby the device can be downsized. Moreover, since an OS transistor has smaller variations in electrical characteristics than a Si transistor even in a high-temperature environment, the semiconductor device can function as a highly reliable memory device in which stacked and integrated transistors have small variations in electrical characteristics.

The structure described in this embodiment can be used in an appropriate combination with the structures described in the other embodiments and the like.

### Embodiment 8

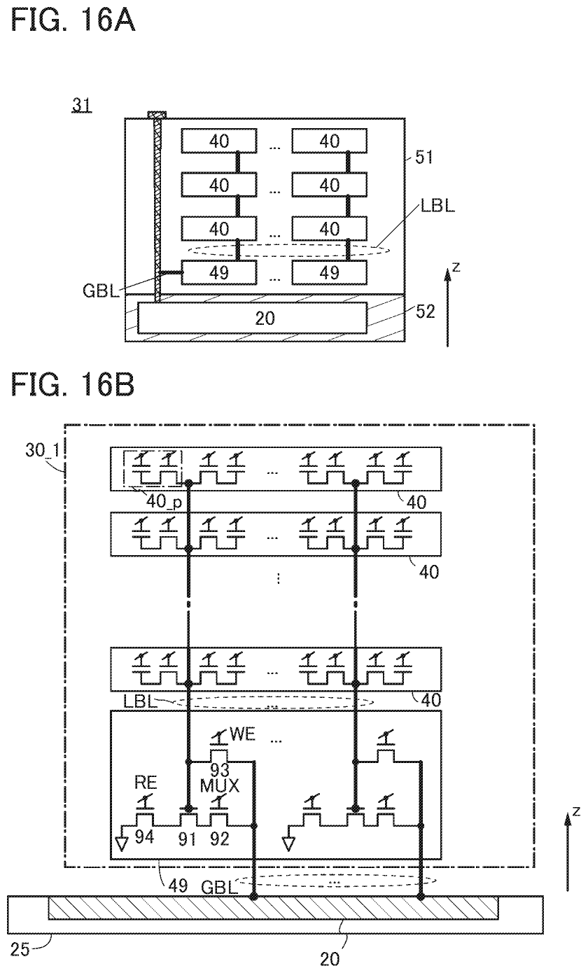

In this embodiment, a modification example of a circuit applicable to the semiconductor device described above in Embodiments 1 to 6 is described with reference to FIG. 16A and FIG. 16B.

FIG. 16A illustrates a structure example in which, in a structure of a semiconductor device including a memory cell layer stacked over a substrate, an amplifier circuit capable of amplifying a data signal retained in a memory cell is provided.

FIG. 16A is a block diagram of the memory cell layer 31 that is applicable to the memory cell layers 31_1 to the memory cell layer 31_N described in Embodiment 1. The memory cell layer 31 includes an amplifier circuit 49 between the peripheral circuit 20 provided in the substrate 52 and a plurality of the memory cells 40 provided in the element layer 51.

In order to explain the position of each component, the z-axis direction is defined in a schematic diagram illustrated in FIG. 16A. Note that for easy understanding, the z-axis direction is sometimes referred to as a direction perpendicular to a surface of the substrate 52 in this specification. In FIG. 16A, in the element layer 51 provided over the substrate 52, the amplifier circuit 49 and the plurality of memory cells 40 are provided by stacking transistors in the z-axis direction.

The amplifier circuit 49 is provided between a wiring LBL for connecting the plurality of memory cells 40 to each other and a wiring GBL for connecting the peripheral circuit 20 and a circuit thereabove. The amplifier circuit 49 includes a circuit that has a function of amplifying a potential of the wiring LBL connected to the memory cells 40 and transmitting the amplified potential to the wiring GBL connected to the peripheral circuit 20 and a function of transmitting a potential of the peripheral circuit 20 to the wiring LBL connected to the memory cells 40. The wiring GBL may be referred to as a global bit line. The wiring LBL may be referred to as a local bit line. The wiring LBL and the wiring GBL have functions of bit lines for data writing to or data reading from the memory cells. Note that in some drawings, the wiring LBL and the wiring GBL are denoted by thick lines, thick dotted lines, or the like to increase visibility.

FIG. 16B illustrates a circuit structure example of the amplifier circuit 49. The amplifier circuit 49 includes transistors 91 to 94. Each of the transistors 91 to 94 can be an OS transistor and is illustrated as an n-channel transistor.

The transistor 91 is a transistor for controlling the potential of the wiring GBL to a potential corresponding to the potential of the wiring LBL in a period during which data is read from the memory cells 40. The transistor 92 is a transistor functioning as a switch where a selection signal MUX is input to a gate and ON or OFF between a source and a drain is controlled in accordance with the selection signal MUX. The transistor 93 is a transistor functioning as a switch where a write control signal WE is input to a gate and ON or OFF between a source and a drain is controlled in accordance with the write control signal WE. The transistor 94 is a transistor functioning as a switch where a read control signal RE is input to a gate and ON or OFF between a source and a drain is controlled in accordance with the read control signal RE. Note that the ground potential GND, which is a fixed potential, is supplied to the source side of the transistor 94.

The semiconductor device of one embodiment of the present invention can be manufactured by repeatedly forming transistors in the perpendicular direction over the substrate by employing the same manufacturing process. In one embodiment of the present invention, the memory density can be increased by arranging the OS transistors included in the memory cells in not a plane direction but the perpendicular direction, whereby the device can be downsized. In the case where the memory cell layer 31 has the structure including the amplifier circuit 49, the wiring LBL is connected to the gate of the transistor 91, whereby a data signal can be read to the wiring GBL by utilizing a slight potential difference of the wiring LBL.

The structure described in this embodiment can be used in an appropriate combination with the structures described in the other embodiments and the like.

### Embodiment 9

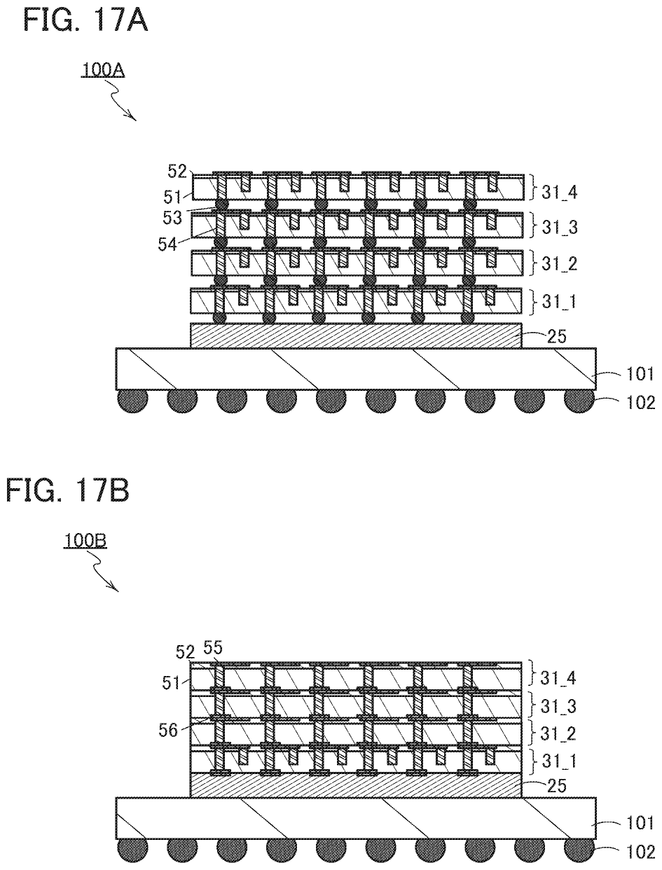

In this embodiment, an example of an integrated circuit (referred to as an IC chip) including the semiconductor devices 10A to 10F is described. The semiconductor device 10 can be one IC chip by mounting a plurality of dies on a packaging substrate. FIG. 17A and FIG. 17B illustrate an example of the structure.

In a schematic cross-sectional diagram of an IC chip 100A illustrated in FIG. 17A, the substrate 25 is positioned over a package substrate 101 and, for example, four memory cell layers 31_1 and 31_4 are stacked over the substrate 25. Solder balls 102 for connecting the IC chip 100A to a printed circuit board or the like are provided on the packaging substrate 101. The memory cell layers 31_1 to 31_4 can be stacked by repeating the structure in which an OS transistor is formed in the element layer 51 in contact with the substrate 52. Furthermore, the peripheral circuit provided in the silicon substrate and each circuit such as the memory cells included in the memory cell layers 31_1 to 31_4 can be connected by the through electrodes 54 in TSVs (Through Silicon Vias) or the like which are provided to penetrate the substrate 52 and the element layer 51 in each layer. In addition, the layers can be electrically connected to each other via the through electrodes 54 provided to penetrate each layer and the metal bumps 53 (also referred to as the micro-bumps) provided between the layers.

For another example, in a schematic cross-sectional diagram of an IC chip 100B illustrated in FIG. 17B, the substrate 25 is positioned over the package substrate 101 and, for example, four memory cell layers 31_1 and 31_4 are stacked over the substrate 25. The peripheral circuit (not illustrated) provided in the substrate 25 and each circuit of the memory cells (not illustrated) included in the memory cell layers 31_1 and 31_4 are bonded to each other using an electrode 55 and an electrode 56 provided in the substrate 52 and the element layer 51 in each layer. As a technique for electrically bonding different layers using the electrode 55 and the electrode 56, Cu—Cu bonding can be used. Cu—Cu bonding is a technique that establishes electrical continuity by connecting Cu (copper) pads.

### Embodiment 10

An example of a schematic cross-sectional view of a semiconductor device according to one embodiment of the present invention will be described below.

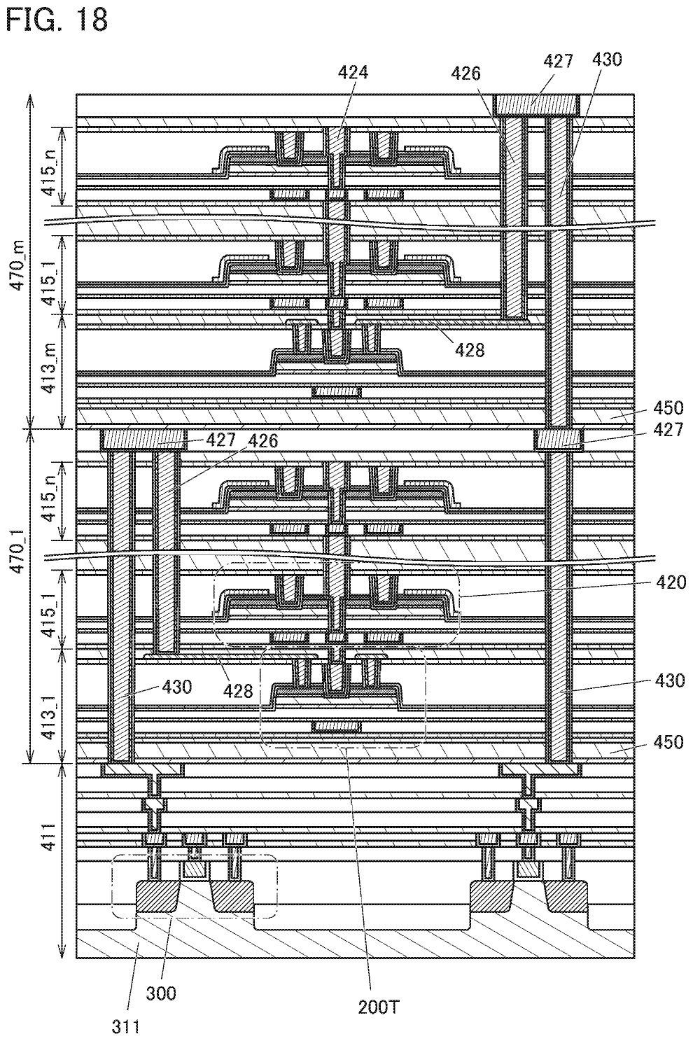

FIG. 18 is a diagram showing an example of a semiconductor device in which memory units 470 (a memory unit 470_1 to a memory unit 470_m: m is an integer greater than or equal to 2, and the case of m=2 is shown in FIG. 18) are stacked and provided over an element layer 411 including a circuit provided on a semiconductor substrate 311. The element layer 411 including the circuit provided on the semiconductor substrate 311 corresponds to the substrate 25 including the peripheral circuit 21 described above in Embodiments 1 to 6 or the like. The memory units correspond to the memory cell layers 31 including the memory cells 40 described above in Embodiments 1 to 6.

FIG. 18 shows the element layer 411 and the plurality of memory units 470 stacked over the element layer 411. An example is shown in which the plurality of memory units 470 are each provided with a transistor layer 413 (a transistor layer 413_1 to a transistor layer 413_m) corresponding to each memory unit 470 on a substrate 450 and a plurality of memory device layers (a memory device layer 415_1 to a memory device layer 415_n: n is an integer greater than or equal to 2) over each transistor layer 413. Note that although the example is shown in which the transistor layer 413 is provided on the substrate 450 and the memory device layers 415 are provided over the transistor layer 413 in each memory unit 470, this embodiment is not limited thereto. The plurality of memory device layers 415 may be provided on the substrate 450 and the transistor layers 413 may be provided over the plurality of memory device layers 415, or the memory device layers 415 may be provided on the substrate 450 and over and under the transistor layers 413. The transistor layers 413 corresponds to layers including the transistors included in the amplifier circuit 49 described above in Embodiment 8 or the like. The memory device layers correspond to layers including the transistors included in the memory cells 40 described above in Embodiments 1 to 6 or the like.

As each of materials included in the semiconductor substrate 311 and the substrate 450, a material selected from Si, Ge, SiGe, GaAs, GaAlAs, GaN, and InP can be used.

The element layer 411 includes a transistor 300 provided on the semiconductor substrate and can function as a circuit (referred to as a peripheral circuit in some cases) of the semiconductor device. Examples of the circuit include a column driver, a row driver, a column decoder, a row decoder, a sense amplifier, a precharge circuit, an amplifier circuit, a word line driver circuit, an output circuit, a control logic circuit, and the like.

The transistor layer 413 includes a transistor 200T and can function as a circuit that controls each memory unit 470. The memory device layer 415 includes a memory device 420. The memory device 420 described in this embodiment includes a transistor and a capacitor.

Note that although not particularly limited, m described above is greater than or equal to and less than or equal to 100, preferably greater than or equal to 2 and less than or equal to 50, further preferably greater than or equal to 2 and less than or equal to 10. In addition, although not particularly limited, n described above is greater than or equal to 2 and less than or equal to 100, preferably greater than or equal to 2 and less than or equal to 50, further preferably greater than or equal to 2 and less than or equal to 10. Furthermore, the product of m and n described above is greater than or equal to 4 and less than or equal to 256, preferably greater than or equal to 4 and less than or equal to 128, further preferably greater than or equal to 4 and less than or equal to 64.

In addition, FIG. 18 shows a cross-sectional view in the channel length direction of the transistor 200T included in the memory unit and the transistor included in the memory device 420.

As shown in FIG. 18, the transistor 300 is provided on the semiconductor substrate 311, and the transistor layers 413 and the memory device layers 415 included in the memory units 470 are provided over the transistor 300. In one memory unit 470, the transistor 200T included in the transistor layer 413 and the memory devices 420 included in the memory device layers 415 are electrically connected to each other by a plurality of conductors 424, and the transistor 300 and the transistor 200T included in the transistor layer 413 in each memory unit 470 are electrically connected to each other by a conductor 426, a conductor 427, and a conductor 430. In addition, the conductor 426 is preferably electrically connected to the transistor 200T through a conductor that is electrically connected to any one of a source, a drain, and a gate of the transistor 200T. The conductor 424 is preferably provided in each layer in the memory device layer 415. The conductor 427 is provided as an uppermost layer of each memory unit 470 and is electrically connected to the conductor 426 and the conductor 430.

As each of materials included in the conductor 426, the conductor 427, and the conductor 430, a material selected from Cu, W, Ti, Ta, and Al can be used.

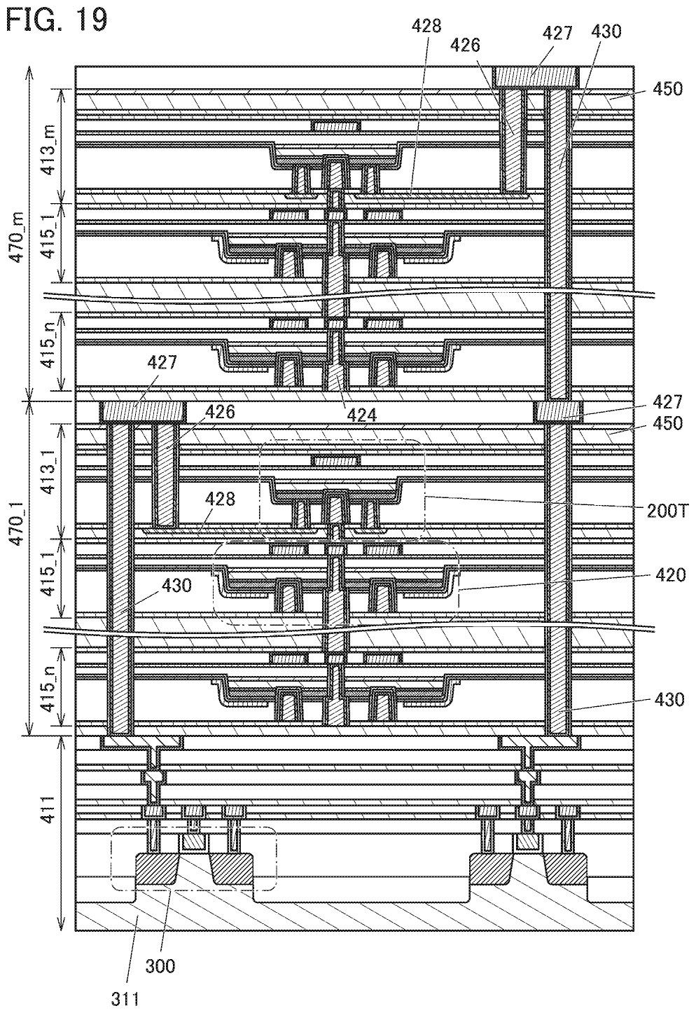

Note that although FIG. 18 shows the example in which the substrate 450 of the memory unit 470 is provided on the transistor 300 side, this embodiment is not limited thereto. As shown in FIG. 19, the memory unit 470 may be provided such that the memory device layer 415 is provided on the transistor 300 side.

In FIG. 18, the conductor 426 is provided to pass through the memory device layer 415, and the conductor 430 is provided to pass through the memory device layer 415, the transistor layer 413, and the substrate 450.

In contrast, in FIG. 19, the conductor 426 is provided to pass through the substrate 450 and the transistor layer 413, and the conductor 430 is provided to pass through the substrate 450, the transistor layer 413, and the memory device layer 415.

In order to suppress leakage between the conductor 426 and the conductor 430, each side surface of the conductor 426 and the conductor 430 is preferably provided with an insulator.

In addition, although the details are described later, an insulator that inhibits passage of impurities such as water or hydrogen, or oxygen is preferably provided on each of a side surface of the conductor 424 and a side surface of the conductor 426. For such an insulator, for example, silicon nitride, aluminum oxide, or silicon nitride oxide is used.

The memory device 420 includes the transistor and the capacitor on a side surface of the transistor, and the transistor can have a structure similar to that of the transistor 200T included in the transistor layer 413.

Here, in the transistor 200T, a metal oxide functioning as an oxide semiconductor (hereinafter also referred to as an oxide semiconductor) is preferably used for a semiconductor that includes a region where a channel is formed (hereinafter also referred to as a channel formation region).

As the oxide semiconductor, for example, a metal oxide such as an In—M—Zn oxide (the element M is one kind or a plurality of kinds of aluminum, gallium, yttrium, tin, copper, vanadium, beryllium, boron, titanium, iron, nickel, germanium, zirconium, molybdenum, lanthanum, cerium, neodymium, hafnium, tantalum, tungsten, magnesium, and the like) is preferably used. Alternatively, as the oxide semiconductor, indium oxide, an In—Ga oxide, or an In—Zn oxide, that is, an oxide semiconductor containing In, Ga, and Zn may be used. Note that when an oxide semiconductor having a high proportion of indium is used, the on-state current, field-effect mobility, or the like of the transistor can be increased.

The transistor 200T using an oxide semiconductor in its channel formation region has an extremely low leakage current in a non-conduction state; thus, a semiconductor device with low power consumption can be provided. In addition, an oxide semiconductor can be deposited by a sputtering method or the like and thus can be used in the transistor 200T included in a highly integrated semiconductor device.

In contrast, a transistor using an oxide semiconductor easily has normally-on characteristics (characteristics such that a channel exists without voltage application to a gate electrode and a current flows through a transistor) owing to an impurity and an oxygen vacancy in the oxide semiconductor that change electrical characteristics.

In view of this, an oxide semiconductor with a reduced impurity concentration and a reduced density of defect states is preferably used. Note that in this specification and the like, a state with a low impurity concentration and a low density of defect states is referred to as a highly purified intrinsic or substantially highly purified intrinsic state.

Accordingly, the impurity concentration in the oxide semiconductor is preferably reduced as much as possible. Note that examples of impurities in the oxide semiconductor include hydrogen, nitrogen, alkali metal, alkaline earth metal, iron, nickel, silicon, and the like.

In particular, hydrogen as an impurity that is contained in the oxide semiconductor might form an oxygen vacancy (Vo) in the oxide semiconductor. In addition, in some cases, a defect that is an oxygen vacancy into which hydrogen enters (hereinafter sometimes referred to as VoH) generates an electron serving as a carrier. Furthermore, in other cases, reaction between part of hydrogen and oxygen bonded to a metal atom generates an electron serving as a carrier.

Thus, a transistor using an oxide semiconductor with a high hydrogen content is likely to be normally on. In addition, hydrogen in the oxide semiconductor is easily transferred by stress such as heat or an electric field; thus, a high hydrogen content in the oxide semiconductor might decrease the reliability of the transistor.

Therefore, it is preferable to use a highly purified intrinsic oxide semiconductor in which impurities such as hydrogen and oxygen vacancies are reduced as the oxide semiconductor used in the transistor 200T.

The structure described in this embodiment can be used in an appropriate combination with the structures described in the other embodiments and the like.

### Embodiment 11

In this embodiment, details of the peripheral circuit 20 including circuits for driving the memory cell array including the memory cells 40 in the semiconductor device 10 described in Embodiments 1 to 6 will be described.

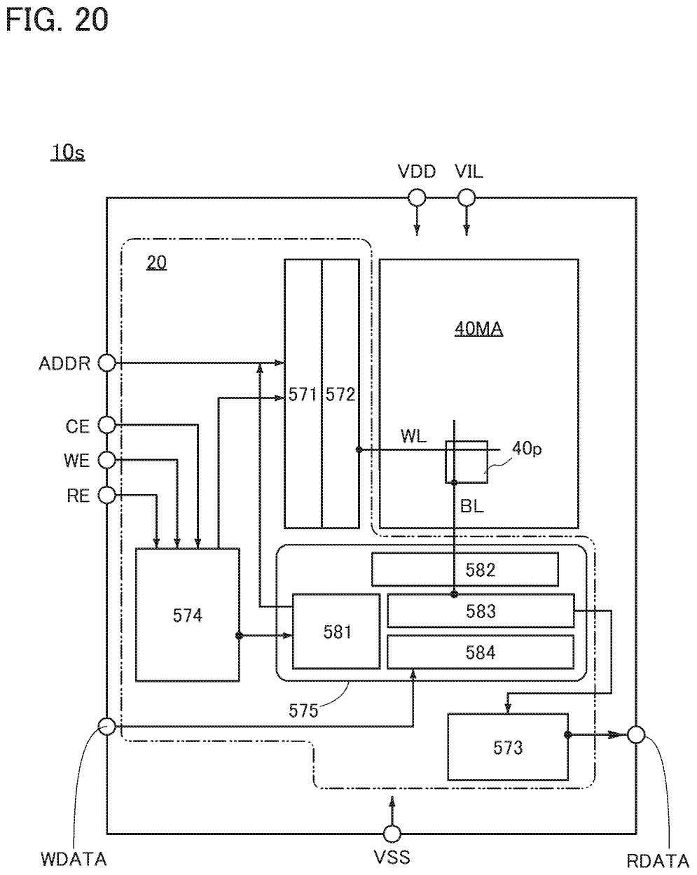

FIG. 20 is a block diagram illustrating a structure example of a semiconductor device functioning as a memory device. A semiconductor device 10s includes the peripheral circuit 20 and a memory cell array 40MA. The peripheral circuit 20 includes a row decoder 571, a word line driver circuit 572, a column driver 575, an output circuit 573, and a control logic circuit 574.

The column driver 575 includes a column decoder 581, a precharge circuit 582, an amplifier circuit 583, and a write circuit 584. The precharge circuit 582 has a function of precharging the wiring BL and the like. The amplifier circuit 583 has a function of amplifying a data signal read from the wiring BL. The amplified data signal is output to the outside of the semiconductor device 10s as a digital data signal RDATA through the output circuit 573. As power supply voltage from the outside, low power supply voltage (VS S), high power supply voltage (VDD) for the peripheral circuit 20, and high power supply voltage (VIL) for the memory cell array 40MA are supplied to the semiconductor device 10s.

Control signals (CE, WE, and RE), an address signal ADDR, and a data signal WDATA are also input to the semiconductor device 10s from the outside. The address signal ADDR is input to the row decoder 571 and the column decoder 581, and WDATA is input to the write circuit 584.

The control logic circuit 574 processes the signals (CE, WE, and RE) input from the outside, and generates control signals for the row decoder 571 and the column decoder 581. CE is a chip enable signal, WE is a write enable signal, and RE is a read enable signal. The signals processed by the control logic circuit 574 are not limited thereto, and other control signals may be input as necessary. For example, a control signal for determining a defective bit may be input so that a defective bit may be identified with a data signal read from an address of a particular memory cell.

Note that whether each circuit or each signal described above is provided or not can be appropriately determined as needed.

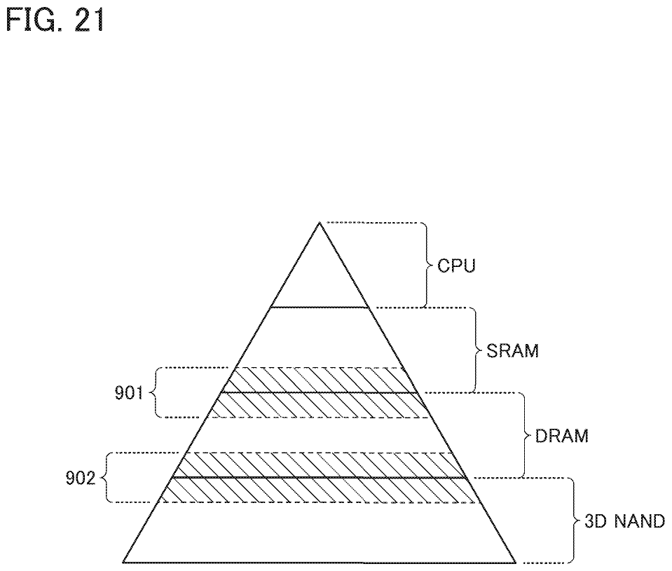

In general, a variety of memory devices (memories) are used in semiconductor devices such as a computer in accordance with the intended use. FIG. 21 shows a hierarchy diagram showing a variety of memory devices with different levels. The memory devices at the upper levels of the diagram require higher access speed, and the memory devices at the lower levels require larger memory capacity and higher memory density. FIG. 21 illustrates, sequentially from the top level, a memory combined as a register in an arithmetic processing unit such as a CPU, an SRAM (Static Random Access Memory), a DRAM (Dynamic Random Access Memory), and a 3D NAND memory.

A memory combined as a register in an arithmetic processing unit such as a CPU is used for temporary storage of arithmetic operation results, for example, and thus is frequently accessed by the arithmetic processing unit. Accordingly, high operation speed is required rather than memory capacity. In addition, the register also has a function of retaining settings information of the arithmetic processing unit, for example.

An SRAM is used for a cache, for example. The cache has a function of retaining a copy of part of data retained in a main memory. By copying data that is frequently used and retaining the copy of the data in the cache, access speed to the data can be increased.

A DRAM is used for the main memory, for example. The main memory has a function of retaining a program, data, or the like read from a storage. The memory density of a DRAM is approximately 0.1 to 0.3 Gbit/mm².

A 3D NAND memory is used for a storage, for example. A storage has a function of retaining data that needs to be retained for a long time or a variety of programs used in an arithmetic processing unit, for example. Therefore, a storage needs to have high memory capacity and high memory density rather than operating speed. The memory density of a memory device used for a storage is approximately 0.6 to 6.0 Gbit/mm².

The semiconductor device functioning as the memory device of one embodiment of the present invention operates fast and can retain data for a long time. The semiconductor device of one embodiment of the present invention can be suitably used as a semiconductor device positioned in a boundary region 901 including both the level in which a cache is positioned and the level in which a main memory is positioned. Furthermore, the semiconductor device of one embodiment of the present invention can be suitably used as a semiconductor device positioned in a boundary region 902 including both the level in which a main memory is positioned and the level in which a storage is positioned.

### Embodiment 12

In this embodiment, examples of electronic components and electronic devices in which the semiconductor device or the like described in the above embodiment is incorporated will be described.

### <Electronic Component>

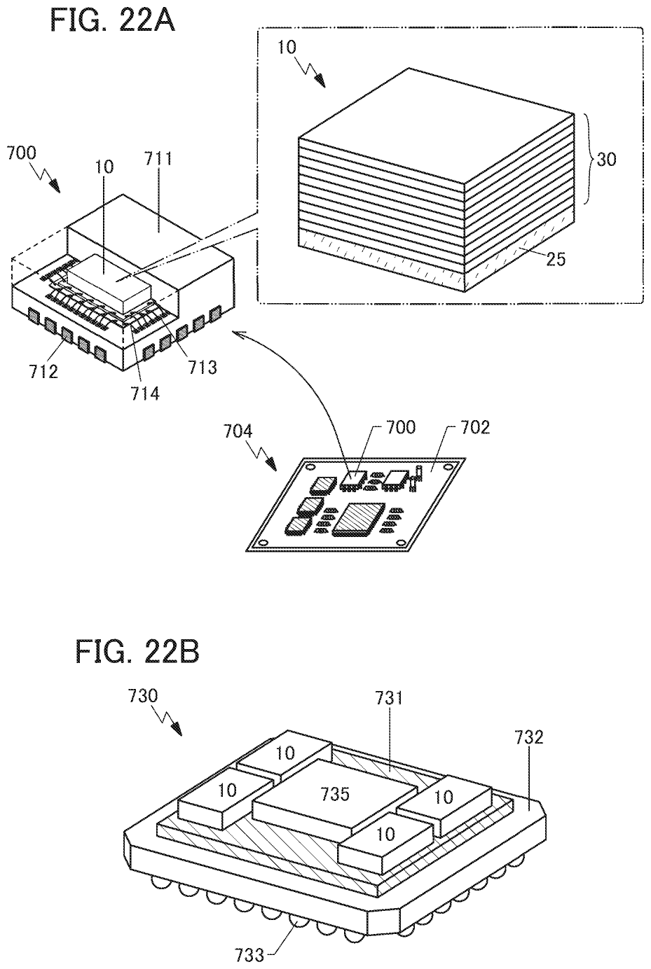

First, examples of electronic components in which the semiconductor device 10 or the like is incorporated are described using FIG. 22A and FIG. 22B.

FIG. 22((A) illustrates a perspective view of an electronic component 700 and a substrate (a mounting board 704) on which the electronic component 700 is mounted. The electronic component 700 illustrated in FIG. 22((A) includes the semiconductor device 10 in which the memory cell layers 30 are stacked over the silicon substrate 25 in a mold 711. The semiconductor device 10 can be used as the semiconductor devices 10A to 10F described in Embodiment 1. Part of the electronic component is not reflected on FIG. 22A so that FIG. 22A illustrates the inside of the electronic component 700. The electronic component 700 includes a land 712 outside the mold 711. The land 712 is electrically connected to an electrode pad 713, and the electrode pad 713 is electrically connected to the semiconductor device 10 via a wire 714. The electronic component 700 is mounted on a printed circuit board 702, for example. A plurality of such electronic components are combined and electrically connected to each other on the printed circuit board 702, so that the mounting board 704 is completed.

FIG. 22B illustrates a perspective view of an electronic component 730. The electronic component 730 is an example of a SiP (System in package) or an MCM (Multi Chip Module). In the electronic component 730, an interposer 731 is provided on a packaging substrate 732 (a printed circuit board), and a semiconductor device 735 and a plurality of semiconductor devices are provided on the interposer 731.

The electronic component 730 using the semiconductor devices 10 as high bandwidth memory (HBM) is illustrated as an example. In addition, an integrated circuit (semiconductor device) such as a CPU, a GPU, or an FPGA can be used for the semiconductor device 735.

As the packaging substrate 732, a ceramic substrate, a plastic substrate, a glass epoxy substrate, or the like can be used. As the interposer 731, a silicon interposer, a resin interposer, or the like can be used.

The interposer 731 includes a plurality of wirings and has a function of electrically connecting a plurality of integrated circuits with different terminal pitches. The plurality of wirings are provided in a single layer or multiple layers. In addition, the interposer 731 has a function of electrically connecting an integrated circuit provided on the interposer 731 to an electrode provided on the packaging substrate 732. Accordingly, the interposer is sometimes referred to as a “redistribution substrate” or an “intermediate substrate”. Furthermore, a through electrode is provided in the interposer 731 and the through electrode is used to electrically connect an integrated circuit and the packaging substrate 732 in some cases. Moreover, for a silicon interposer, a TSV (Through Silicon Via) can also be used as the through electrode.

A silicon interposer is preferably used as the interposer 731. A silicon interposer can be manufactured at lower cost than an integrated circuit because it is not necessary to provide an active element. Meanwhile, since wirings of a silicon interposer can be formed through a semiconductor process, formation of minute wirings, which is difficult for a resin interposer, is easy.

In order to achieve a wide memory bandwidth, many wirings need to be connected to HBM. Therefore, formation of minute and high-density wirings is required for an interposer on which HBM is mounted. For this reason, a silicon interposer is preferably used as the interposer on which HBM is mounted.

In addition, in a SiP, an MCM, or the like using a silicon interposer, the decrease in reliability due to a difference in expansion coefficient between an integrated circuit and the interposer is less likely to occur. Furthermore, a silicon interposer has high surface flatness, so that a poor connection between the silicon interposer and an integrated circuit provided on the silicon interposer is less likely to occur. It is particularly preferable to use a silicon interposer for a 2.5D package (2.5-dimensional mounting) in which a plurality of integrated circuits are arranged side by side on an interposer.

In addition, a heat sink (a radiator plate) may be provided to overlap the electronic component 730. In the case where a heat sink is provided, the heights of integrated circuits provided on the interposer 731 are preferably aligned with each other. For example, in the electronic component 730 described in this embodiment, the heights of the semiconductor devices and the semiconductor device 735 are preferably aligned with each other.

To mount the electronic component 730 on another substrate, an electrode 733 may be provided on the bottom portion of the packaging substrate 732. FIG. 22B illustrates an example in which the electrode 733 is formed of a solder ball. When solder balls are provided in a matrix on the bottom portion of the packaging substrate 732, BGA (Ball Grid Array) mounting can be achieved. Alternatively, the electrode 733 may be formed of a conductive pin. When conductive pins are provided in a matrix on the bottom portion of the packaging substrate 732, PGA (Pin Grid Array) mounting can be achieved.

The electronic component 730 can be mounted on another substrate by various mounting methods, not limited to BGA and PGA. For example, a mounting method such as SPGA (Staggered Pin Grid Array), LGA (Land Grid Array), QFP (Quad Flat Package), QFJ (Quad Flat J-leaded package), or QFN (Quad Flat Non-leaded package) can be used.

### <Electronic Device>

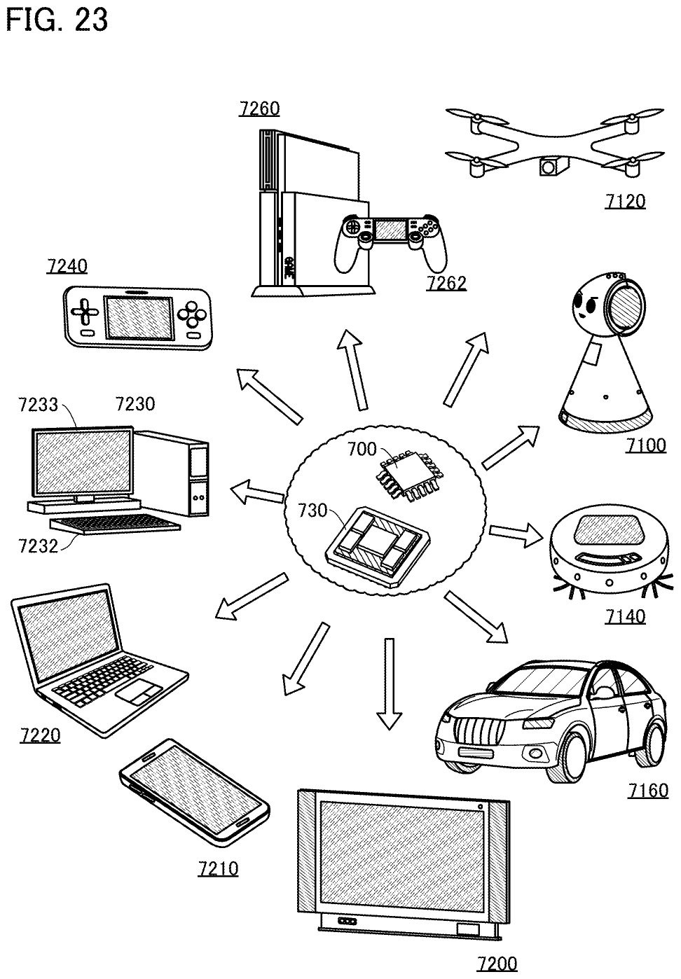

Next, examples of electronic devices including the electronic component are described using FIG. 23.

A robot 7100 includes an illuminance sensor, a microphone, a camera, a speaker, a display, various kinds of sensors (an infrared ray sensor, an ultrasonic wave sensor, an acceleration sensor, a piezoelectric sensor, an optical sensor, a gyro sensor, and the like), a moving mechanism, and the like. The electronic component 730 includes a processor or the like and has a function of controlling these peripheral devices. For example, the electronic component 700 has a function of storing data obtained by the sensors.

The microphone has a function of detecting acoustic signals of a voice of a user, an environmental sound, and the like. In addition, the speaker has a function of outputting audio signals such as a voice and a warning beep. The robot 7100 can analyze an audio signal input via the microphone and can output a necessary audio signal from the speaker. The robot 7100 can communicate with the user with the use of the microphone and the speaker.

The camera has a function of taking images of the surroundings of the robot 7100. In addition, the robot 7100 has a function of moving with the use of the moving mechanism. The robot 7100 can take images of the surroundings with the use of the camera and analyze the images to sense whether there is an obstacle in the way of the movement, for example.

A flying object 7120 includes propellers, a camera, a battery, and the like and has a function of flying autonomously. The electronic component 730 has a function of controlling these peripheral devices.

For example, image data taken by the camera is stored in the electronic component 700. The electronic component 730 can analyze the image data to sense whether there is an obstacle in the way of the movement, for example. Moreover, the electronic component 730 can estimate the remaining battery level from a change in the power storage capacity of the battery.

A cleaning robot 7140 includes a display provided on a top surface, a plurality of cameras provided on a side surface, a brush, an operation button, various kinds of sensors, and the like. Although not illustrated, the cleaning robot 7140 is provided with a tire, an inlet, and the like. The cleaning robot 7140 can run autonomously, detect dust, and vacuum the dust through the inlet provided on a bottom surface.

For example, the electronic component 730 can analyze images taken by the cameras to judge whether there is an obstacle such as a wall, furniture, or a step. In the case where an object that is likely to be caught in the brush, such as a wire, is detected by image analysis, the rotation of the brush can be stopped.

A motor vehicle 7160 includes an engine, tires, a brake, a steering gear, a camera, and the like. For example, the electronic component 730 performs control for optimizing the running state of the motor vehicle 7160 on the basis of navigation information, the speed, the state of the engine, the gearshift state, the use frequency of the brake, and other data. For example, image data taken by the camera is stored in the electronic component 700.

The electronic component 700 and/or the electronic component 730 can be incorporated in a TV device 7200 (a television receiver), a smartphone 7210, PCs (personal computers) 7220 and 7230, a game machine 7240, a game machine 7260, and the like.

For example, the electronic component 730 incorporated in the TV device 7200 can function as an image processing engine. The electronic component 730 performs, for example, image processing such as noise removal and resolution up-conversion.

The smartphone 7210 is an example of a portable information terminal. The smartphone 7210 includes a microphone, a camera, a speaker, various kinds of sensors, and a display portion. These peripheral devices are controlled by the electronic component 730.

The PC 7220 and the PC 7230 are respectively examples of a laptop PC and a desktop PC. To the PC 7230, a keyboard 7232 and a monitor device 7233 can be connected with or without a wire. The game machine 7240 is an example of a portable game machine. The game machine 7260 is an example of a stationary game machine. To the game machine 7260, a controller 7262 is connected with or without a wire. The electronic component 700 and/or the electronic component 730 can also be incorporated in the controller 7262.

This embodiment can be implemented in an appropriate combination with the structures described in the other embodiments and the like.

<Supplementary Notes on the Description in this Specification and the Like>

The description of the above embodiments and each structure in the embodiments are noted below.

One embodiment of the present invention can be constituted by combining, as appropriate, the structure described in each embodiment with the structures described in the other embodiments. In addition, in the case where a plurality of structure examples are described in one embodiment, the structure examples can be combined as appropriate.

Note that content (or may be part of the content) described in one embodiment can be applied to, combined with, or replaced with another content (or may be part of the content) described in the embodiment and/or content (or may be part of the content) described in another embodiment or other embodiments.

Note that in each embodiment, content described in the embodiment is content described using a variety of diagrams or content described with text disclosed in the specification. Note that by combining a diagram (or may be part thereof) described in one embodiment with another part of the diagram, a different diagram (or may be part thereof) described in the embodiment, and/or a diagram (or may be part thereof) described in another embodiment or other embodiments, much more diagrams can be formed.

In addition, in this specification and the like, components are classified on the basis of the functions, and shown as blocks independent of one another in block diagrams. However, in an actual circuit or the like, it is difficult to separate components on the basis of the functions, and there can be a case where one circuit is associated with a plurality of functions or a case where a plurality of circuits are associated with one function. Therefore, blocks in the block diagrams are not limited by the components described in this specification, and the description can be changed appropriately depending on the situation.

Furthermore, in the drawings, the size, the layer thickness, or the region is shown with given magnitude for description convenience. Therefore, the size, the layer thickness, or the region is not necessarily limited to the illustrated scale. Note that the drawings are schematically shown for clarity, and embodiments of the present invention are not limited to shapes, values or the like shown in the drawings. For example, variation in signal, voltage, or current due to noise, variation in signal, voltage, or current due to difference in timing, or the like can be included. In this specification and the like, expressions “one of a source and a drain” (or a first electrode or a first terminal) and “the other of the source and the drain” (or a second electrode or a second terminal) are used in the description of the connection relationship of a transistor. This is because the source and the drain of the transistor change depending on the structure, operating conditions, or the like of the transistor. Note that the source or the drain of the transistor can also be referred to as a source (drain) terminal, a source (drain) electrode, or the like as appropriate depending on the situation.

In addition, in this specification and the like, the terms “electrode” and “wiring” do not functionally limit these components. For example, an “electrode” is used as part of a “wiring” in some cases, and vice versa. Furthermore, the terms “electrode” and “wiring” also include the case where a plurality of “electrodes” and a plurality of “wirings” are formed in an integrated manner, for example.

Furthermore, in this specification and the like, “voltage” and “potential” can be interchanged with each other as appropriate. The voltage refers to a potential difference from a reference potential, and when the reference potential is a ground voltage, for example, the voltage can be rephrased into the potential. The ground potential does not necessarily mean 0 V. Note that potentials are relative values, and a potential applied to a wiring or the like is sometimes changed depending on the reference potential.

In this specification and the like, the terms “film” and “layer” can be interchanged with each other depending on the case or circumstances. For example, the term “conductive layer” can be changed into the term “conductive film” in some cases. Also, for example, the term “insulating film” can be changed into the term “insulating layer” in some cases.

In this specification and the like, a switch has a function of controlling whether current flows or not by being in a conduction state (an on state) or a non-conduction state (an off state). Alternatively, a switch has a function of selecting and changing a current path.

In this specification and the like, channel length refers to, for example, the distance between a source and a drain in a region where a semiconductor (or a portion where current flows in a semiconductor when a transistor is in an on state) and a gate overlap with each other or a region where a channel is formed in a top view of the transistor.

In this specification and the like, channel width refers to, for example, the length of a portion where a source and a drain face each other in a region where a semiconductor (or a portion where current flows in a semiconductor when a transistor is in an on state) and a gate electrode overlap with each other or a region where a channel is formed.

In this specification and the like, the expression “A and B are connected” means the case where A and B are electrically connected to each other as well as the case where A and B are directly connected to each other. Here, the expression “A and B are electrically connected” means the case where electric signals can be transmitted and received between A and B when an object having any electric action exists between A and B.

### REFERENCE NUMERALS

10A: semiconductor device, 20: peripheral circuit, 25: substrate, 30: memory cell layer, 31_1: memory cell layer, 31_2: memory cell layer, 31_N: memory cell layer, 40_1: memory cell, 40_2: memory cell, 40_N: memory cell, 40p: memory circuit, 40: memory cell, 41: transistor, 42: capacitor

1. A semiconductor device comprising:
a first substrate provided with a first peripheral circuit configured to drive a first memory cell; and
a first memory cell layer comprising a second substrate and a first element layer comprising the first memory cell,
wherein the first memory cell comprises a first transistor and a first capacitor,
wherein the first transistor comprises a semiconductor layer comprising a metal oxide in its channel formation region,
wherein the first memory cell layer is provided to be stacked over the first substrate in a direction perpendicular or substantially perpendicular to a surface of the first substrate, and
wherein the first peripheral circuit and the first memory cell are electrically connected to each other through a first through electrode provided in the second substrate and the first element layer.

2. A semiconductor device comprising:
a first substrate provided with a first peripheral circuit configured to drive a first memory cell; and
a first memory cell layer comprising a second substrate and a first element layer comprising the first memory cell,
wherein the first memory cell comprises a first transistor and a first capacitor,
wherein the first transistor comprises a semiconductor layer comprising a metal oxide in its channel formation region,
wherein the first memory cell layer is provided to be stacked over the first substrate in a direction perpendicular or substantially perpendicular to a surface of the first substrate,
wherein the second substrate comprises an amplifier circuit for performing writing of data to or reading of data from the first memory cell, and
wherein the first peripheral circuit and the first memory cell are electrically connected to each other through a first through electrode provided in the second substrate and the first element layer.

3. The semiconductor device according to claim 1,
wherein the first memory cell layer comprises a plurality of the first element layers provided to be stacked in a direction perpendicular or substantially perpendicular to the surface of the first substrate.

4. The semiconductor device according to claim 1, comprising:
the first substrate provided with a second peripheral circuit configured to drive a second memory cell; and
a third substrate provided with a second memory cell layer comprising a second element layer comprising the second memory cell,
wherein the first memory cell layer is provided between the first substrate and the second memory cell layer,
wherein the second memory cell comprises a second transistor and a second capacitor,
wherein the second transistor comprises a semiconductor layer comprising silicon in its channel formation region, and
wherein the second peripheral circuit and the second memory cell are electrically connected to each other through a second through electrode provided in the second substrate, the third substrate, the first element layer, and the second element layer.

5. The semiconductor device according to claim 4,
wherein the first substrate comprises a CPU, and
wherein the second memory cell is configured to retain data retained by the CPU.

6. The semiconductor device according to claim 1, comprising:
the first substrate provided with a second peripheral circuit configured to drive a second memory cell; and
a second memory cell layer comprising a third substrate and a second element layer comprising the second memory cell,
wherein the first memory cell layer is provided between the first substrate and the second memory cell layer,
wherein the second memory cell comprises a third transistor to a fifth transistor and a third capacitor,
wherein the third transistor to the fifth transistor comprise semiconductor layers comprising a metal oxide in their channel formation regions, and
wherein the second peripheral circuit and the second memory cell are electrically connected to each other through a second through electrode provided in the second substrate, the third substrate, the first element layer, and the second element layer.

7. The semiconductor device according to claim 1,
wherein the metal oxide comprises In, Ga, and Zn.

8. The semiconductor device according to claim 2,
wherein the first memory cell layer comprises a plurality of the first element layers provided to be stacked in a direction perpendicular or substantially perpendicular to the surface of the first substrate.

9. The semiconductor device according to claim 2, comprising:
the first substrate provided with a second peripheral circuit configured to drive a second memory cell; and
a third substrate provided with a second memory cell layer comprising a second element layer comprising the second memory cell,
wherein the first memory cell layer is provided between the first substrate and the second memory cell layer,
wherein the second memory cell comprises a second transistor and a second capacitor,
wherein the second transistor comprises a semiconductor layer comprising silicon in its channel formation region, and
wherein the second peripheral circuit and the second memory cell are electrically connected to each other through a second through electrode provided in the second substrate, the third substrate, the first element layer, and the second element layer.

10. The semiconductor device according to claim 9,
wherein the first substrate comprises a CPU, and
wherein the second memory cell is configured to retain data retained by the CPU.

11. The semiconductor device according to claim 2, comprising:
the first substrate provided with a second peripheral circuit configured to drive a second memory cell; and
a second memory cell layer comprising a third substrate and a second element layer comprising the second memory cell,
wherein the first memory cell layer is provided between the first substrate and the second memory cell layer,
wherein the second memory cell comprises a third transistor to a fifth transistor and a third capacitor,
wherein the third transistor to the fifth transistor comprise semiconductor layers comprising a metal oxide in their channel formation regions, and
wherein the second peripheral circuit and the second memory cell are electrically connected to each other through a second through electrode provided in the second substrate, the third substrate, the first element layer, and the second element layer.

12. The semiconductor device according to claim 2,
wherein the metal oxide comprises In, Ga, and Zn.
